(19) United States
(12) Patent Application Publication
(10) Pub. No.: US 2025/0374576 A1
(43) Pub. Date: Dec. 4, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Jui Fu CHUEH, Hsinchu (TW); Shih-Yao LIN, Hsinchu (TW)

(73) Assignee: Taiwan Semiconductor Manufacturing Company, Ltd., Hsinchu (TW)

(21) Appl. No.: 18/900,251

(22) Filed: Sep. 27, 2024

Related U.S. Application Data
(60) Provisional application No. 63/655,428, filed on Jun. 3, 2024.

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017

(57) ABSTRACT

Manufacturing method of semiconductor device includes forming first and second multilayer stacks over a substrate. First and second multilayer stacks include plurality of spaced apart nanosheets arranged along first direction of stack, and dielectric spacers disposed between adjacent nanosheets. A mask layer is formed over first and second multilayer stacks. A first portion of mask layer over first multilayer stack is removed to expose plurality of nanosheets and dielectric spacers of first multilayer stack. A portion of the dielectric spacers of first multilayer stack along second direction perpendicular to first direction of stack is removed to decrease thickness of dielectric spacers of first multilayer stack along second direction. A second portion of the mask layer over second multilayer stack is removed to expose plurality of nanosheets and dielectric spacers of second multilayer stack, and gate structures are wrapped around plurality of nanosheets of first and second multilayer stacks.

### RELATED APPLICATION

This application claims priority to U.S. Provisional Application No. 63/655,428 filed Jun. 3, 2024, the entire disclosure of which is incorporated herein by reference.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET) including a fin FET (FinFET) and a gate-all-around (GAA) FET. In a FinFET, a gate electrode is adjacent to three side surfaces of a channel region with a gate dielectric layer interposed therebetween. Because the gate structure surrounds (wraps) the fin on three surfaces, the transistor essentially has three gates controlling the current through the fin or channel region. In a GAA FET, all side surfaces of the channel region are surrounded by the gate electrode, which allows for fuller depletion in the channel region and result in less short-channel effects due to steeper sub-threshold current swing (SS) and smaller drain induced barrier lowering (DIBL). As transistor dimensions are continually scaled down to sub 20-25 nm technology nodes, further improvements of the GAA FET are required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a cross sectional view of one of the various stages of manufacturing a GAA FET semiconductor device according to an embodiment of the present disclosure.

FIG. 2A shows a cross sectional view and FIG. 2B shows an isometric view of one of the various stages of manufacturing a GAA FET semiconductor device according to embodiments of the present disclosure.

FIG. 3A shows a cross sectional view and FIG. 3B shows an isometric view of one of the various stages of manufacturing a GAA FET semiconductor device according to embodiments of the present disclosure.

FIG. 4 shows a cross sectional view of one of the various stages of manufacturing a GAA FET semiconductor device according to an embodiment of the present disclosure.

FIG. 5 shows a cross sectional view of one of the various stages of manufacturing a GAA FET semiconductor device according to an embodiment of the present disclosure.

FIG. 6 shows a cross sectional view of one of the various stages of manufacturing a GAA FET semiconductor device according to an embodiment of the present disclosure.

FIG. 7 shows a cross sectional view of one of the various stages of manufacturing a GAA FET semiconductor device according to an embodiment of the present disclosure.

FIG. 8 shows a cross sectional view of one of the various stages of manufacturing a GAA FET semiconductor device according to an embodiment of the present disclosure.

FIG. 9 shows a cross sectional view of one of the various stages of manufacturing a GAA FET semiconductor device according to an embodiment of the present disclosure.

FIGS. 10A and 10B show a cross sectional view and an isometric view of one of the various stages of manufacturing a GAA FET semiconductor device according to an embodiment of the present disclosure.

FIG. 11 shows a cross sectional view of one of the various stages of manufacturing a GAA FET semiconductor device according to an embodiment of the present disclosure.

FIG. 12 shows a cross sectional view of one of the various stages of manufacturing a GAA FET semiconductor device according to an embodiment of the present disclosure.

FIG. 13 shows a cross sectional view of one of the various stages of manufacturing a GAA FET semiconductor device according to an embodiment of the present disclosure.

FIG. 14 shows a cross sectional view of one of the various stages of manufacturing a GAA FET semiconductor device according to an embodiment of the present disclosure.

FIG. 15 shows a cross sectional view of one of the various stages of manufacturing a GAA FET semiconductor device according to an embodiment of the present disclosure.

FIG. 16 shows a cross sectional view of one of the various stages of manufacturing a GAA FET semiconductor device according to an embodiment of the present disclosure.

FIG. 17 shows a cross sectional view of one of the various stages of manufacturing a GAA FET semiconductor device according to an embodiment of the present disclosure.

FIG. 18 shows a cross sectional view of one of the various stages of manufacturing a GAA FET semiconductor device according to an embodiment of the present disclosure.

FIG. 19 shows a cross sectional view of one of the various stages of manufacturing a GAA FET semiconductor device according to an embodiment of the present disclosure.

FIG. 20 shows a cross sectional view of one of the various stages of manufacturing a GAA FET semiconductor device according to an embodiment of the present disclosure.

FIG. 21 shows a cross sectional view of one of the various stages of manufacturing a GAA FET semiconductor device according to an embodiment of the present disclosure.

FIGS. 22A and 22B show cross sectional views of one of the various stages of manufacturing a GAA FET semiconductor device according to an embodiment of the present disclosure.

FIG. 23 shows a cross sectional view of one of the various stages of manufacturing a GAA FET semiconductor device according to an embodiment of the present disclosure.

FIGS. 24A and 24B show cross sectional views of one of the various stages of manufacturing a GAA FET semiconductor device according to an embodiment of the present disclosure.

FIG. 25 shows a cross sectional view of one of the various stages of manufacturing a GAA FET semiconductor device according to an embodiment of the present disclosure.

FIGS. 26A and 26B show cross sectional views of one of the various stages of manufacturing a GAA FET semiconductor device according to an embodiment of the present disclosure.

FIGS. 27A and 27B show cross sectional views of one of the various stages of manufacturing a GAA FET semiconductor device according to an embodiment of the present disclosure.

FIG. 28 shows a cross sectional view of one of the various stages of manufacturing a GAA FET semiconductor device according to an embodiment of the present disclosure.

FIGS. 29A and 29B show cross sectional views of one of the various stages of manufacturing a GAA FET semiconductor device according to an embodiment of the present disclosure.

FIGS. 30A and 30B show cross sectional views of one of the various stages of manufacturing a GAA FET semiconductor device according to an embodiment of the present disclosure.

FIGS. 31A and 31B show cross sectional views of one of the various stages of manufacturing a GAA FET semiconductor device according to an embodiment of the present disclosure.

FIGS. 32A and 32B show cross sectional views of one of the various stages of manufacturing a GAA FET semiconductor device according to an embodiment of the present disclosure.

FIGS. 33A and 33B show cross sectional views of one of the various stages of manufacturing a GAA FET semiconductor device according to an embodiment of the present disclosure.

FIG. 34 shows a cross sectional view of one of the various stages of manufacturing a GAA FET semiconductor device according to an embodiment of the present disclosure.

FIGS. 35A and 35B show cross sectional views of one of the various stages of manufacturing a GAA FET semiconductor device according to an embodiment of the present disclosure.

FIG. 36 shows a cross sectional view of one of the various stages of manufacturing a GAA FET semiconductor device according to an embodiment of the present disclosure.

FIG. 37A, show cross sectional views of one of the various stages of manufacturing a GAA FET semiconductor device according to an embodiment of the present disclosure. FIGS. 37B and 37C show detailed views of FIG. 37A.

FIG. 38 shows a flow chart for a method of manufacturing a semiconductor device according to embodiments of the present disclosure.

FIG. 39 shows a flow chart for a method of manufacturing a semiconductor device according to embodiments of the present disclosure.

FIG. 40 shows a flow chart for a method of manufacturing a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. Source/drain structure(s) may refer to a source or a drain, individually or collectively dependent upon the context. In the following embodiments, materials, configurations, dimensions, processes and/or operations as described with respect to one embodiment (e.g., one or more figures) may be employed in the other embodiments, and detailed description thereof may be omitted.

Disclosed embodiments relate to a semiconductor device, in particular, a gate structure of a gate-all-around field effect transistor (GAA FET) and a stacked channel FET and their manufacturing methods.

In embodiments of the disclosure, the width of inner spacers between the gate electrode and the source/drain regions of a GAA FET are reduced, thereby reducing the capacitance of the inner spacer between the gate electrodes and the source/drain regions. By reducing the capacitance, the DC performance of the GAA FET device can be improved. In some embodiments of the disclosure, the width of the inner spacer is optimized for different transistors within a semiconductor device.

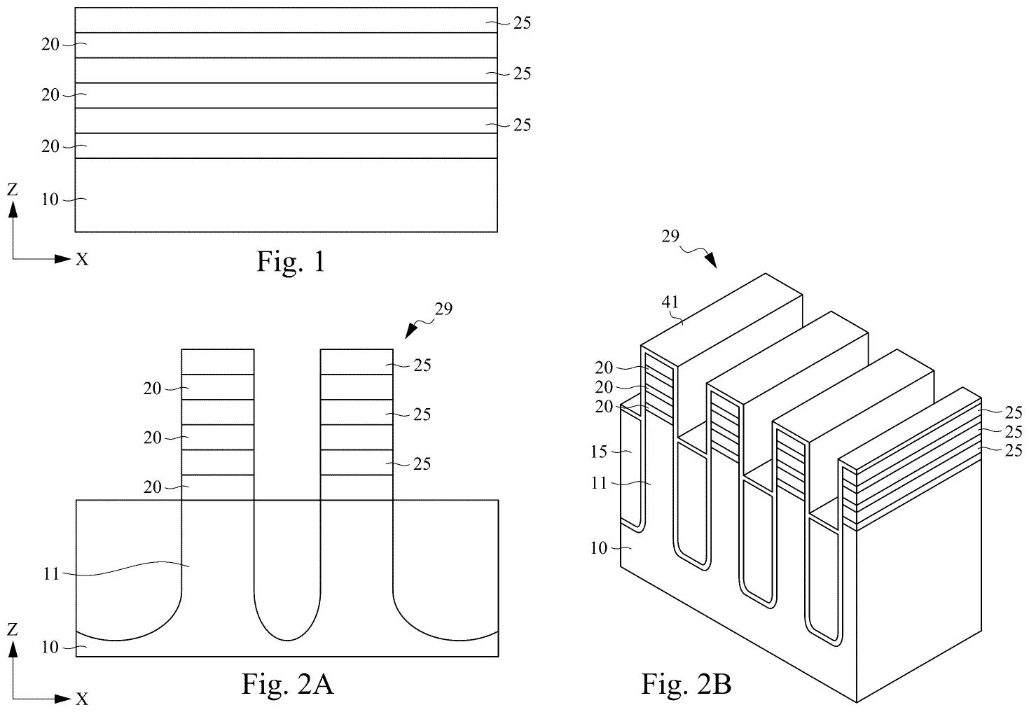

FIGS. 1 to 13 are schematic illustrations showing various stages of manufacturing a semiconductor FET device according to an embodiment of the present disclosure. It is understood that additional operations can be provided before, during, and after processes shown by FIGS. 1-13, and some of the operations described below can be replaced or eliminated, for additional embodiments of the method. The order of the operations/processes may be interchangeable.

As shown in FIG. 1, first semiconductor layers 20 and second semiconductor layers 25 are alternately formed over a substrate 10. The first semiconductor layers 20 and the second semiconductor layers 25 are made of materials having different lattice constants, and may include one or more layers of Si, Ge, SiGe, GaAs, InSb, GaP, GaSb, InAlAs, InGaAs, GaSbP, GaAsSb or InP.

In some embodiments, the first semiconductor layers 20 and the second semiconductor layers 25 are made of Si, a Si compound, SiGe, Ge or a Ge compound. In some embodiments, the first semiconductor layers 20 are made of Si. In some embodiments, the first semiconductor layers 20 are made of Si₁₋ₓGeₓ, where x is equal to or more than about 0.1 and equal to or less than about 0.6, and the second semiconductor layers 25 are Si or Si_{1-y}Ge_{y}, where y is smaller than x and equal to or less than about 0.2. In this disclosure, an “M” compound” or an “M based compound” means the majority of the compound is M.

In other embodiments, the second semiconductor layers 25 are made of Si₁₋ₓGeₓ, where x is equal to or more than about 0.1 and equal to or less than about 0.6, and the first semiconductor layers 20 are made of Si or Si_{1-y}Ge_{y}, where y is smaller than x and equal to or less than about 0.2.

In some embodiments, the second semiconductor layer 25 is made of the same material as the semiconductor substrate 10.

The thickness of the semiconductor layers 25 in the Z-direction is in a range from about 5 nm to about 60 nm and the width of the semiconductor layers 25 along the Y-direction is in a range from about 5 nm to about 80 nm in some embodiments. In some embodiments, the width of the semiconductor layers is greater than the thickness. In certain embodiments, the width is up to twice or five times the thickness of the semiconductor nanostructures 25.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. The substrate 10 may include various regions that have been suitably doped with impurities (e.g., p-type or n-type conductivity). The dopants are, for example, boron difluoride (BF₂) for an n-type Fin FET and phosphorus for a p-type Fin FET in some embodiments. In certain embodiments, the substrate 10 is made of crystalline Si.

The substrate 10 may include in its surface region, one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

The first semiconductor layer 20 and the second semiconductor layer 25 may be formed by one or more epitaxy or epitaxial (epi) processes. The epitaxy processes include chemical vapor deposition (CVD) deposition techniques (e.g., vapor-phase epitaxy (VPE) and/or ultra-high vacuum CVD (UHV-CVD)), molecular beam epitaxy, and/or other suitable processes.

The first semiconductor layers 20 and the second semiconductor layers 25 are epitaxially formed over the substrate 10 alternately. The thickness of the first semiconductor layers 20 may be equal to or greater than that of the second semiconductor layers 25, and is in a range from about 4 nm to about 30 nm in some embodiments, and is in a range from about 5 nm to about 15 nm in other embodiments. The thickness of the second semiconductor layers 25 is in a range from about 4 nm to about 30 nm in some embodiments, and is in a range from about 5 nm to about 15 nm in other embodiments. The thickness of the first semiconductor layers 20 may be the same as, or different from the thickness of the second semiconductor layers 25. Although three first semiconductor layers 20 and three second semiconductor layers 25 are shown in FIG. 1, the numbers are not limited to three, and can be one, two, or more than 3, and less than twenty. In some embodiments, the number of the first semiconductor layers 20 is greater by one than the number of the second semiconductor layers 25 (i.e.—the top and bottom layers are the first semiconductor layer).

After the stacked semiconductor layers are formed, fin structures 29 are formed by using one or more lithography and etching operations, as shown in FIGS. 2A and 2B. The fin structures may be patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

As shown in FIG. 2A, the fin structures 29 extend in the X direction and are arranged in the Y direction. The number of the fin structures is not limited to two as shown in FIG. 2A, and may be as small as one and three or more (as shown in FIG. 2B). In some embodiments, one or more dummy fin structures are formed on both sides of the fin structures 29 to improve pattern fidelity in the patterning operations. As shown in FIG. 2A, the fin structures 29 have upper portions constituted by the stacked semiconductor layers 20, 25 and well portions 11 (a mesa structure).

The width of the upper portion of the fin structure 29 along the Y direction is in a range from about 5 nm to about 80 nm in some embodiments, and is in a range from about 10 nm to about 40 nm in other embodiments.

After the fin structures 29 are formed, an insulating material layer including one or more layers of insulating material is formed over the substrate so that the fin structures are fully embedded in the insulating layer. The insulating material for the insulating layer may include silicon oxide, silicon nitride, silicon oxynitride (SiON), SiOCN, SiCN, fluorine-doped silicate glass (FSG), or a low-k dielectric material, formed by LPCVD (low pressure chemical vapor deposition), plasma-enhanced CVD (PECVD) or flowable CVD. An anneal operation may be performed after the formation of the insulating layer. Then, a planarization operation, such as a chemical mechanical polishing (CMP) method and/or an etch-back method, is performed such that the upper surface of the uppermost second semiconductor layer 25 is exposed from the insulating material layer. In some embodiments, one or more fin liner layers are formed over the fin structures before forming the insulating material layer. In some embodiments, the fin liner layers include a first fin liner layer formed over the substrate 10 and sidewalls of the bottom part of the fin structures 11, and a second fin liner layer formed on the first fin liner layer. The fin liner layers are made of silicon nitride or a silicon nitride-based material (e.g., SiON, SiCN or SiOCN), in some embodiments. The fin liner layers may be deposited through one or more processes such as physical vapor deposition (PVD), chemical vapor deposition (CVD), or atomic layer deposition (ALD), although any acceptable process may be utilized.

Then, as shown in FIG. 2A, the insulating material layer is recessed to form an isolation insulating layer 15 so that the upper portions of the fin structures 29 are exposed. With this operation, the fin structures 29 are separated from each other by the isolation insulating layer 15, which is also called a shallow trench isolation (STI). The isolation insulating layer 15 may be made of suitable dielectric materials, such as silicon oxide, silicon nitride, silicon oxynitride, fluorine-doped silicate glass (FSG); low-k dielectrics, such as carbon doped oxides; extreme low-k dielectrics, such as porous carbon doped silicon dioxide; a polymer, such as polyimide; combinations of these, or the like. In some embodiments, the isolation insulating layer 15 is formed through a process such as CVD, flowable CVD (FCVD), or a spin-on-glass process, although any acceptable process may be used.

In some embodiments, the insulating material layer 15 is recessed until the upper portion of the fin structure (well layer) 11 is exposed. In other embodiments, the upper portion of the fin structure 11 is not exposed. The first semiconductor layers 20 are sacrificial layers which are subsequently partially removed, and the second semiconductor layers 25 are subsequently formed into semiconductor wires or sheets as channel layers of a GAA FET. In other embodiments, the second semiconductor layers 25 are sacrificial layers which are subsequently partially removed, and the first semiconductor layers 20 are subsequently formed into semiconductor wires or sheets as channel layers.

FIG. 2B is an isometric view showing a plurality of fin structures 29 separated by shallow trench isolations 15 after a sacrificial gate dielectric layer 41 is formed over the fin structures 29 and over the shallow trench isolation 15.

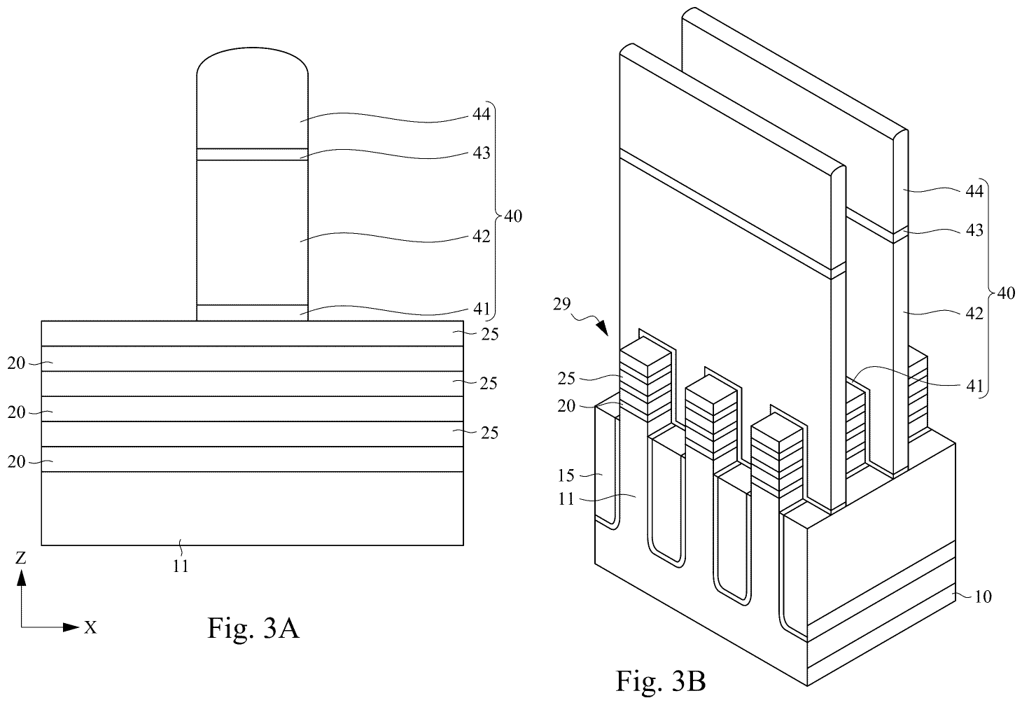

After the isolation insulating layer 15 is formed, one or more sacrificial (dummy) gate structures 40 are formed. FIGS. 3A and 3B illustrate a structure after one or more sacrificial gate structures 40 are formed over the exposed fin structures 29. FIG. 3B is an isometric view of the structure. The sacrificial gate structures 40 are formed over a portion of the fin structures 29 which is to be a channel region. The sacrificial gate structures 40 define the channel regions of the GAA FET. The sacrificial gate structures 40 include a sacrificial gate dielectric layer 41 and a sacrificial gate electrode layer 42. The sacrificial gate dielectric layer 41 includes one or more layers of insulating material, such as a silicon oxide-based material. In one embodiment, silicon oxide formed by CVD is used. The thickness of the sacrificial gate dielectric layer 41 is in a range from about 1 nm to about 5 nm in some embodiments.

The sacrificial gate structures 40 are formed by first blanket depositing the sacrificial gate dielectric layer 41 over the fin structures 29. A sacrificial gate electrode layer 42 is then blanket deposited on the sacrificial gate dielectric layer and over the fin structures, such that the fin structures are fully embedded in the sacrificial gate electrode layer. In some embodiments, the sacrificial gate electrode layer 42 includes silicon such as polycrystalline silicon or amorphous silicon. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. Subsequently, a mask layer is formed over the sacrificial gate electrode layer. In some embodiments, the mask layer includes a pad silicon nitride layer 43 and a silicon oxide mask layer 44.

Next, a patterning operation is performed on the mask layer and sacrificial gate electrode layer is patterned into the sacrificial gate structure 40, as shown in FIGS. 3A and 3B. In an embodiment, the sacrificial gate structure includes the sacrificial gate dielectric layer 41, the sacrificial gate electrode layer 42 (e.g., polysilicon), the pad silicon nitride layer 43 and the silicon oxide mask layer 44. By patterning the sacrificial gate structure, the stacked layers of the first and second semiconductor layers are partially exposed on opposite sides of the sacrificial gate structure, thereby defining source/drain regions, as shown in FIGS. 3A and 3B. In some embodiments, one sacrificial gate structure is formed over one or more fin structures, but the number of the sacrificial gate structures per fin structure is not limited to one. Two or more sacrificial gate structures are arranged in the X direction in some embodiments. In certain embodiments, one or more dummy sacrificial gate structures are formed on both sides of the sacrificial gate structures to improve pattern fidelity.

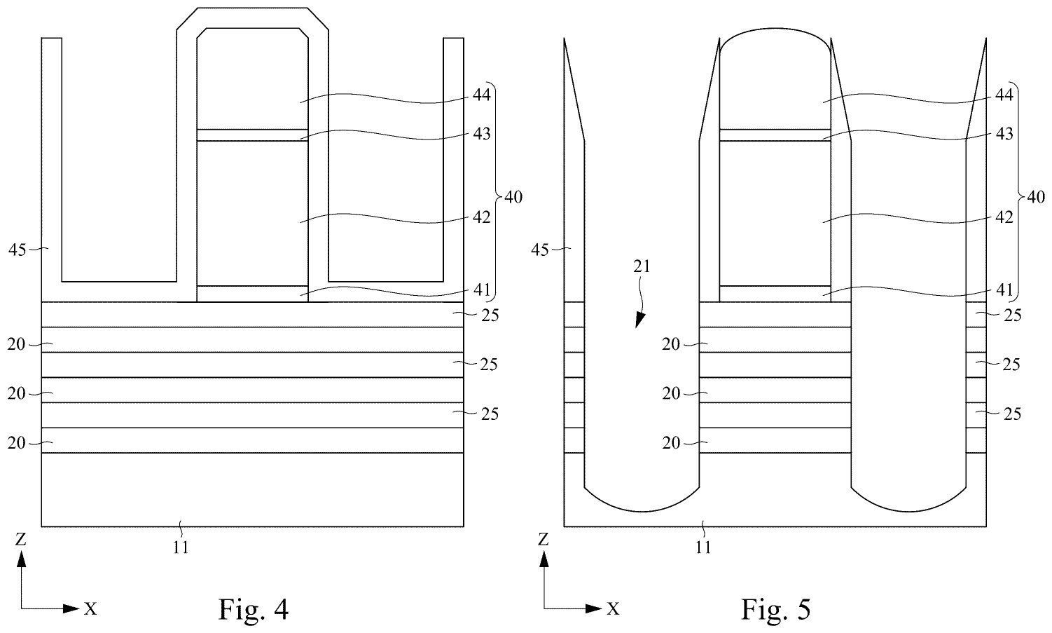

After the sacrificial gate structure 40 is formed, a first cover layer 45 for gate sidewall spacers is formed over the sacrificial gate structure 40, as shown in FIG. 4. The first cover layer 45 is deposited in a conformal manner so that it is formed to have substantially equal thicknesses on vertical surfaces, such as the sidewalls, horizontal surfaces, and the top of the sacrificial gate structure, respectively. In some embodiments, the first cover layer 45 has a thickness in a range from about 5 nm to about 20 nm. The first cover layer 45 includes one or more of silicon nitride, silicon oxide, SiON, SiCN, SiCO, SiOCN or any other suitable dielectric material. The cover layer 45 can be formed by ALD or CVD, or any other suitable method. In some embodiments, one or more additional cover layers are formed over the first cover layer to form multi-layer gate sidewall spacers.

Next, as shown in FIG. 5, the first cover layer 45 is anisotropically etched to remove the first cover layer 45 disposed on the source/drain region, while leaving the first cover layer 45 as sidewall spacers on side faces of the sacrificial gate structure 40. FIG. 5 shows a cross sectional view along the X direction. Then the stacked structure of the first semiconductor layers 20 and the second semiconductor layer 25 is etched down at the source/drain region, by using one or more lithography and etching operations, thereby forming a source/drain space 21. In some embodiments, the substrate 10 (or the bottom part of the fin structures 11) is also partially etched to form a mesa structure. In some embodiments, an n-type FET and a p-type FET are manufactured separately, and in such a case, a region for one type of FET is processed, and a region for the other type of FET is covered by a protective layer, such as a silicon nitride layer. In some embodiments, as shown in FIG. 5, the recessed fin structure has a U-shape. In other embodiments, the recessed fin structure has a V-shape showing (111) facets of silicon crystal. In other embodiments, the recess has a reverse trapezoid shape, or a rectangular shape.

In some embodiments, the recess is formed by a dry etching process, which may be anisotropic. The anisotropic etching process may be performed using a process gas mixture including BF₂, Cl₂, CH₃F, CH₄, HBr, O₂, Ar, and other etchant gases. Process gases may be activated into a plasma by any suitable method of generating the plasma, such as transformer coupled plasma (TCP) systems, inductively coupled plasma (ICP) systems, magnetically enhanced reactive ion techniques. The plasma is a remote plasma that is generated in a separate plasma generation chamber connected to the processing chamber in some embodiments. The process gases used in the plasma etching process includes etchant gases such as H₂, Ar, other gases, or a combination of gases. In some embodiments, carrier gases, such as N₂, Ar, He, Xe, are combined with a plasma etching process gas using hydrogen (H) radicals. The H radicals may be formed by flowing H₂ gas into a plasma generation chamber and igniting a plasma within the plasma generation chamber. In some embodiments, an additional gas may be ignited into a plasma within the plasma generation chamber, such as Ar. The H radicals may selectively etch (100) planes over (111) planes or (110) planes. In some cases, the etch rate of the (100) planes is about three times greater than the etch rate of (111) planes. Due to this selectivity, the etching by the H radicals may tend to slow or stop along (111) planes or (110) planes of silicon during the second patterning process.

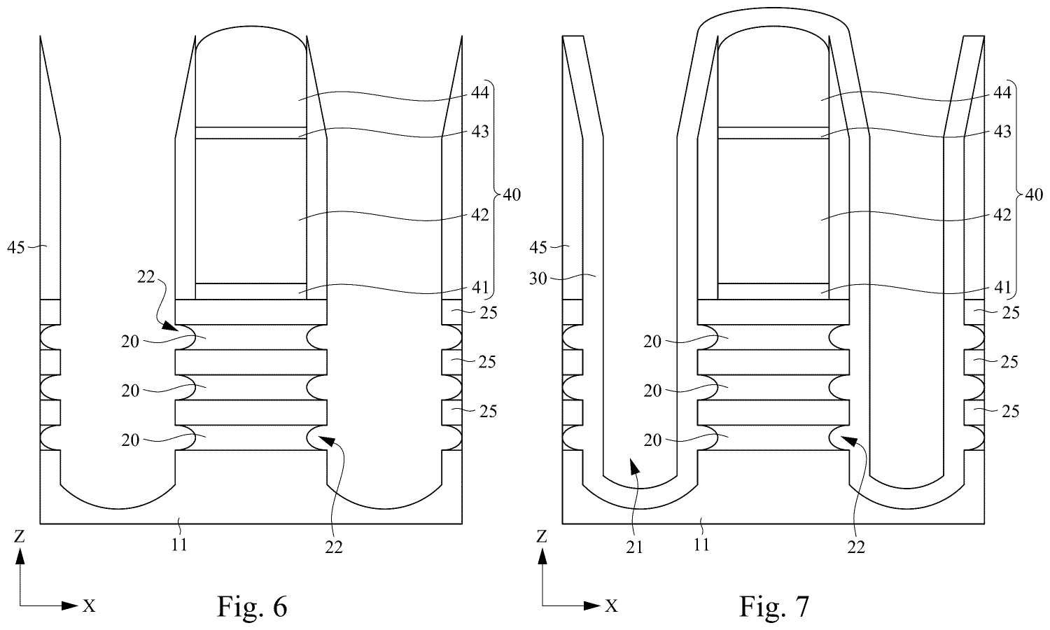

Further, as shown in FIG. 6, the first semiconductor layers 20 are laterally etched in the X direction within the source/drain space 21, thereby forming cavities 22. When the first semiconductor layers 20 are SiGe and the second semiconductor layers 25 are Si, the first semiconductor layers 20 can be selectively etched by using a wet etchant such as, but not limited to, a mixed solution of H₂O₂, CH₃COOH and HF, followed by H₂O cleaning. In some embodiments, the etching by the mixed solution and cleaning by water is repeated 10 to 20 times. The etching time by the mixed solution is in a range from about 1 min to about 2 min in some embodiments. The mixed solution is used at a temperature in a range from about 60° C. to about 90° C. in some embodiments. In some embodiments, other etchants are used.

In some embodiments, the cavity 22 has a curved end shape convex toward the first semiconductor layer 20 (lateral U-shape cross section). In other embodiments, the cavity 22 has a lateral V-shape cross section having an apex at the first semiconductor layer 20.

Next, as shown in FIG. 7, a first insulating layer 30 is formed on the etched lateral ends of the first semiconductor layers 20 and on end faces of the second semiconductor layers 25 in the source/drain space 21 and over the sacrificial gate structure 40. The first insulating layer 30 is conformally formed so that a space is left in the source/drain space 21. The first insulating layer 30 includes one of silicon nitride and silicon oxide, SiON, SiOC, SiCN and SiOCN, or any other suitable dielectric material. The first insulating layer 30 is made of a different material than the sidewall spacers (first cover layer) 45 in some embodiments, and is made of the same material as the sidewall spacers 45 in other embodiments. The first insulating layer 30 can be formed by ALD or any other suitable methods. By forming the first insulating layer 30, the cavities 22 are fully filled with the first insulating layer 30.

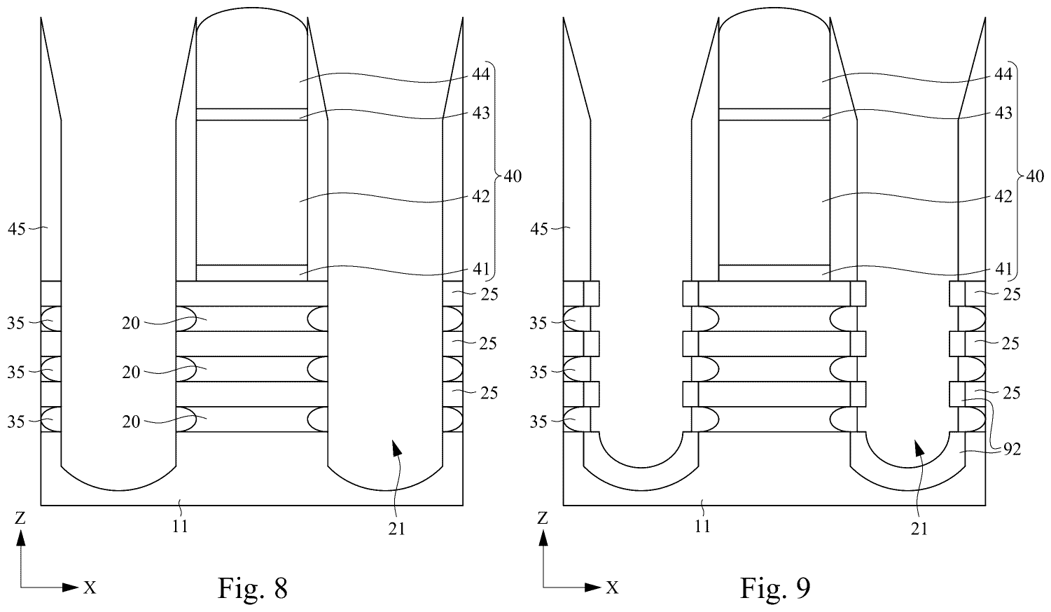

After the first insulating layer 30 is formed, an etching operation is performed to partially remove the first insulating layer 30, thereby forming inner spacers 35, as shown in FIG. 8. In some embodiments, the end face of the inner spacers 35 is recessed more than the end face of the second semiconductor layers 25. The recessed amount is in a range from about 0.2 nm to about 3 nm and is in a range from about 0.5 nm to about 2 nm in other embodiments. In other embodiments, the recessed amount is less than 0.5 nm and may be equal to zero (i.e.—the end face of the inner spacer 35 and the end face of the second semiconductor layers 25 are flush with each other). In some embodiments, before forming the first insulating layer 30, an additional insulating layer having a smaller thickness than the first insulating layer 30 is formed, and thus the inner spacers 35 have a two-layer structure. In some embodiments, widths (lateral length) of the inner spacers 35 are not constant.

After the inner spacers 35 are formed, a first epitaxial layer 92 is formed on lateral end faces of the second semiconductor layer 25 and the exposed surface of the lower fin structure 11 in some embodiments, as shown in FIG. 9. In some embodiments, the first epitaxial layer 92 includes Si doped with P or As for an n-type FET and doped with B for a p-type FET. In some embodiments, the dopant concentration of the first epitaxial layer 92 is higher than the dopant concentration of the second semiconductor layers 25. In some embodiments, the dopant concentration of the first epitaxial layer 92 gradually increases from the interface between the first epitaxial layer 92 and the second semiconductor layers 25 or lower fin structure 11 to the source/drain space 21. In some embodiments, the thickness of the first epitaxial layer 92 as deposited is in a range from about 1 nm to about 10 nm. In some embodiments, during the epitaxial formation of the first epitaxial layer 92, some of the dopant elements diffuse into the second semiconductor layer 25 or lower fin structure 11 to a depth of about 0.5 nm to about 2 nm.

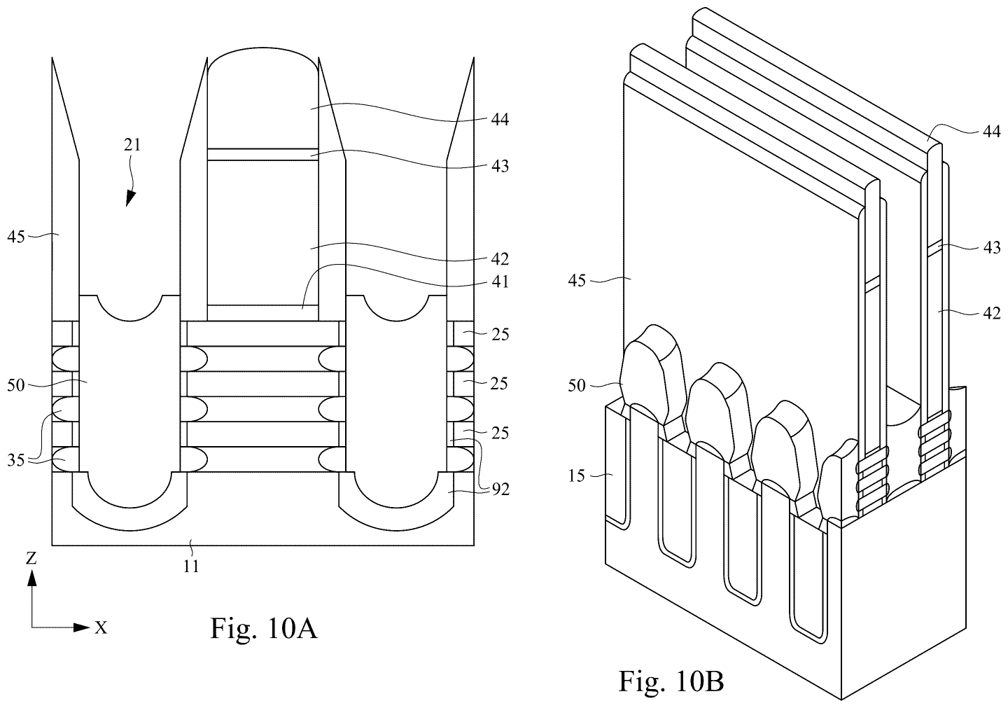

Then, as shown in FIGS. 10A and 10B, source/drain structures 50 are formed in the source/drain space 21. FIG. 10A is a cross section view along the X direction and FIG. 10B is an isometric view of the structure. In some embodiments, source/drain structures 50 include one or more layers of SiC, SiP, SiAs and/or SiCP for an n-type FET. In certain embodiments, SiC or SiCP is used. In some embodiments, the source/drain structure 50 includes SiGe, SiGeSn, Ge, GeSn and/or SiSn for a p-type FET. When SiGe is used, the Ge content is about 60 atomic % to about 80 atomic % in some embodiments. In some embodiments, the source/drain structures 50 are formed by an epitaxial process. In some embodiments, the source/drain structure 50 applies a tensile stress to the second semiconductor layer 25 for an n-type FET and a compressive stress to a p-type FET.

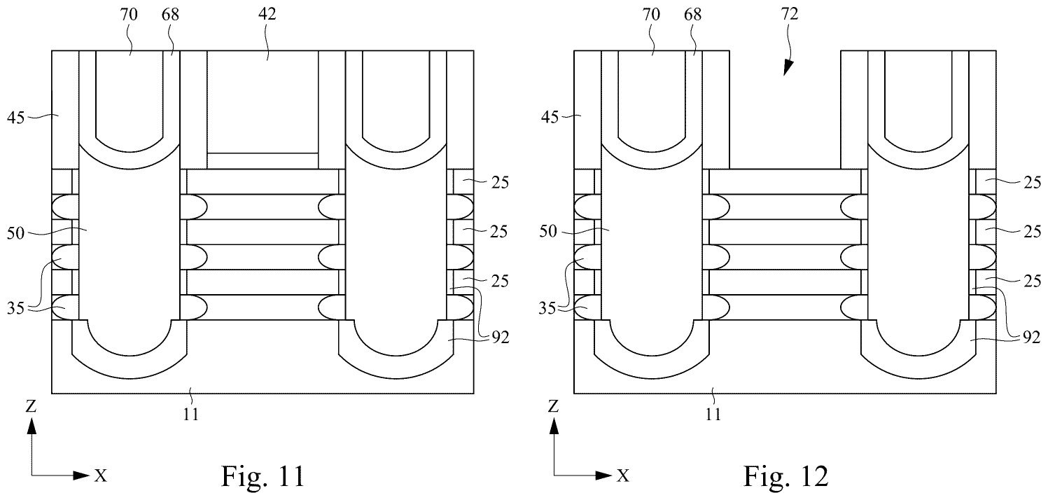

Then, an interlayer dielectric (ILD) layer 70 is formed over the source/drain structure 50 and the sacrificial gate structure 40. In some embodiments, before the ILD layer 70 is formed, a contact etch stop layer 68 is formed. Next, the dielectric layer 70 is planarized by chemical mechanical polishing (CMP) to expose the sacrificial gate electrode layer 42, as shown in FIG. 11. The materials for the ILD layer 70 can include compounds comprising Si, O, C, and/or H, such as a silicon oxide, SiCOH and SiOC. Organic materials, such as a polymer, including polyimide, may be used for the ILD layer 70. Materials for the contact etch stop layer 68 can include a silicon nitride, a silicon oxide, SiCN, SiON, and SiOCN. In some embodiments, the materials for the ILD layer 70 and the etch stop layer 68 are different from each other, and thus have different etch selectivities.

Then, as shown in FIG. 12, the sacrificial gate electrode layer 42 and the sacrificial gate dielectric layer 41 are removed forming a gate space 72. The ILD layer 70 protects the source/drain structures 50 during the removal of the sacrificial gate structures. The sacrificial gate structures can be removed using plasma dry etching and/or wet etching. When the sacrificial gate electrode layer 42 is polysilicon and the dielectric layer 70A is silicon oxide, a wet etchant such as a TMAH solution can be used to selectively remove the sacrificial gate electrode layer 42. The sacrificial gate dielectric layer 41 can thereafter be removed using plasma dry etching and/or wet etching.

After the sacrificial gate structures are removed, the first semiconductor layers 20 are removed, thereby forming nanosheets, nanowires, or nanostructures (channel regions) of the second semiconductor layers 25 stacked along the Z-direction, as shown in FIG. 12. The first semiconductor layers 20 can be removed or etched using an etchant that can selectively etch the first semiconductor layers 20 against the second semiconductor layers 25, as set forth above. Since the inner spacers 35 were previously formed, the etching of the first semiconductor layers 20 stops at the inner spacers 35. In other words, the inner spacers 35 may function as an etch-stop layer for etching of the first semiconductor layers 20. In some embodiments, the inner spacers 35 are etched after the first semiconductor layers are removed, as will be further explained, infra.

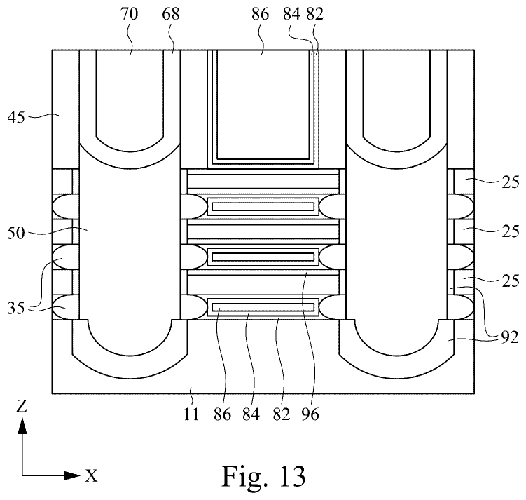

After the semiconductor nanowires or nanosheets (channel regions) of the second semiconductor layers 25 are formed, a metal gate structure is formed as shown in FIG. 13. FIG. 13 is a cross section view along the X direction. In some embodiments, the structure and/or material of the gate electrode for the n-type GAA FET are different from the structure and/or material of the gate electrode for the p-type GAA FET.

In certain embodiments, the gate dielectric layer 82 includes one or more layers of a dielectric material, such as silicon oxide, silicon nitride, or high-k dielectric material, other suitable dielectric material, and/or combinations thereof. High-k dielectric materials have a dielectric constant greater than that of silicon dioxide or greater than about 3.9. Examples of high-k dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate dielectric layer 82 includes an interfacial layer 96 formed between the channel layers and the dielectric material.

The gate dielectric layer 82 may be formed by CVD, ALD or any suitable method. In one embodiment, the gate dielectric layer is formed using a highly conformal deposition process such as ALD in order to ensure the formation of a gate dielectric layer having a uniform thickness around each channel layer. The thickness of the gate dielectric layer 82 is in a range from about 1 nm to about 6 nm in one embodiment.

In some embodiments, the metal gate structure includes one or more work function adjustment layers 84 disposed over the gate dielectric layer 82. The work function adjustment layers 84 are made of a conductive material such as a single layer of TiN, TaN, TaAIC, TiC, TaC, Co, Al, TiAl, HfTi, TiSi, TaSi or TiAIC, or a multilayer of two or more of these materials. In some embodiments, one or more of TiAIC, Al, TiAl, TaN, TaAIC, TIN, TiC and Co are used as the work function adjustment layer for the p-channel FET. For an n-channel FET, one or more of TaN, TaAIC, TIN, TIC, Co, TiAl, HfTi, TiSi and TaSi is used as the work function adjustment layer, according to some embodiments. The work function adjustment layer may be formed by ALD, PVD, CVD, e-beam evaporation, or other suitable process. Further, the work function adjustment layer may be formed separately for the n-channel FET and the p-channel FET which may use different metal layers.

The gate electrode layer 86 is formed on the work function adjustment layer 84 if present or on the gate dielectric layer 82 to surround each channel layer. The gate electrode layer 86 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof.

The gate electrode layer 86 may be formed by CVD, ALD, electro-plating, or other suitable method. The gate electrode layer is also deposited over the upper surface of the ILD layer 70. The gate dielectric layer, work function adjustment layer, and the gate electrode layer formed over the ILD layer 70 are then planarized by using, for example, CMP, until the top surface of the ILD layer 70 is revealed. In some embodiments, after the planarization operation, the gate electrode layer is recessed and a cap insulating layer (not shown) is formed over the recessed gate electrode. In some embodiments, the cap insulating layer includes one or more layers of a silicon nitride-based material, such as silicon nitride. The cap insulating layer is formed by depositing an insulating material followed by a planarization operation.

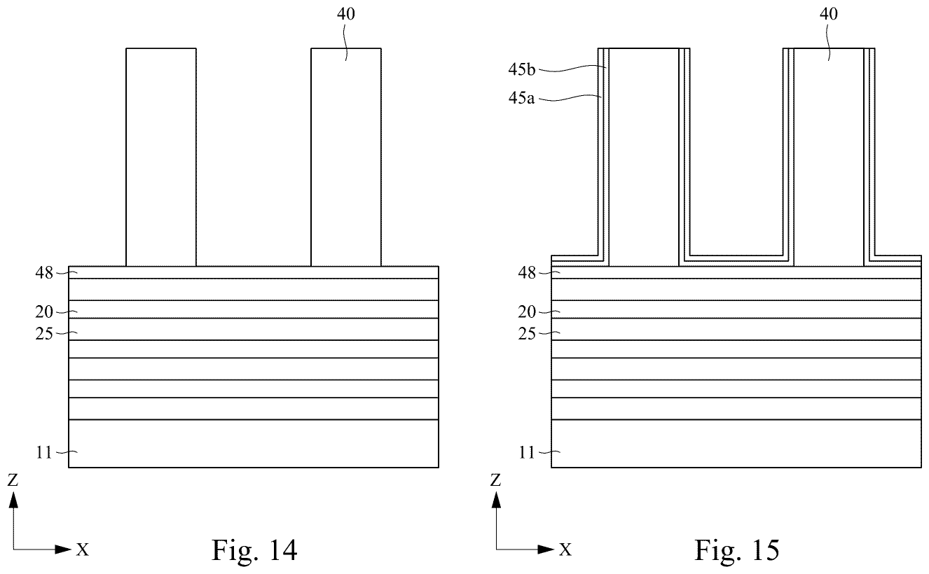

FIGS. 14 to 21 are schematic illustrations showing various stages of manufacturing a semiconductor FET device according to another embodiment of the present disclosure. It is understood that additional operations can be provided before, during, and after processes shown by FIGS. 14-21, and some of the operations described below can be replaced or eliminated, for additional embodiments of the method. The order of the operations/processes may be interchangeable.

After the stacked structure of FIG. 1 is formed, an etch stop layer 48 is formed over the stacked structure and sacrificial gate structures 40 to provide the structure shown in FIG. 14. The etch stop layer 48 is formed by oxidizing the surface of the second semiconductor layer in some embodiments. In other embodiments, the etch stop layer 48 is formed by depositing one or more layers of silicon oxide, silicon nitride, SiON, SiOC, SiOCN, or any other suitable materials using any of the suitable deposition operations disclosed herein. The sacrificial gate structures 40 are formed as explained herein with reference to FIG. 3A in some embodiments.

In some embodiments, a plurality of sidewall spacers, including first gate sidewall spacers 45a and second gate sidewall spacers 45b are formed on sidewalls of the sacrificial gate electrode structure 40, as shown in FIG. 15. The first and second sidewall spacers 45a, 45b include one or more of silicon nitride, silicon oxide, SiON, SiCN, SiCO, SiOCN or any other suitable dielectric material. In some embodiments, the first sidewall spacer 45a is conformally formed over the device structure, then the second sidewall spacer 45b is formed over the first sidewall spacer, and then the structure undergoes a planarization operation, such as CMP, to expose an upper surface of the sacrificial gate electrode layer 42. The sidewall spacers 45a, 45b can be formed by ALD or CVD, or any other suitable method. In some embodiments, the first sidewall spacer 45a and the second sidewall spacer 45b are formed of different materials. In some embodiments, the first sidewall spacer 45a is an oxide, such as silicon oxide, and the second sidewall spacer 45b is a nitride, such as silicon nitride. In other embodiments, the first sidewall spacer 45a is silicon nitride and the second sidewall spacer 45b is silicon oxide.

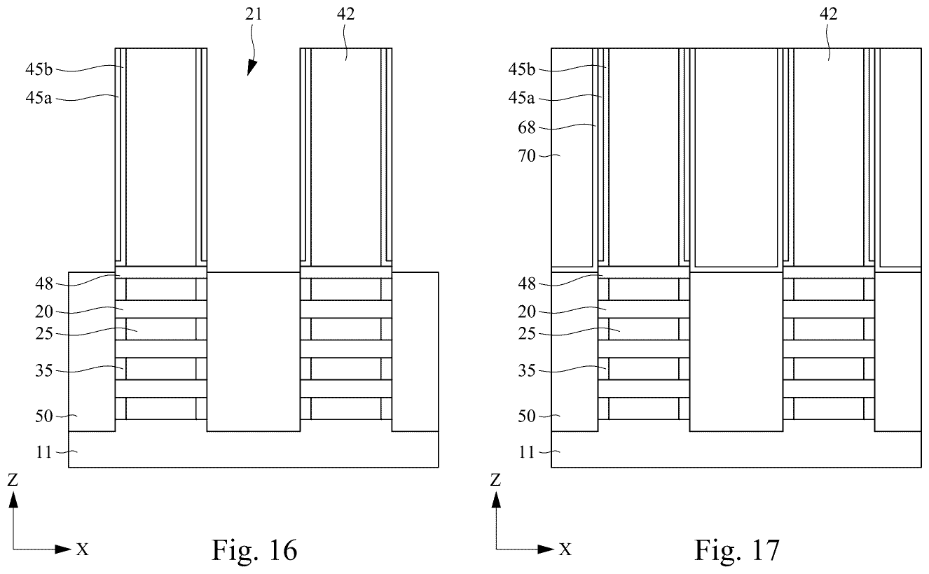

The first and second sidewall spacers 45a, 45b, the etch stop layer 48, and the first and second semiconductor layers 20, 25 are anisotropically etched using suitable etchants. Then in some embodiments, inner spacers 35 and source/drain regions 50 are formed as disclosed herein with reference to FIGS. 5-10B, as shown in FIG. 16.

An interlayer dielectric layer 70 and optionally a contact etch stop layer 68 are subsequently formed over the source/drain regions 50, as shown in FIG. 17. The contact etch stop layer 68 and interlayer dielectric layer 70 may be formed as disclosed herein in reference to FIG. 11.

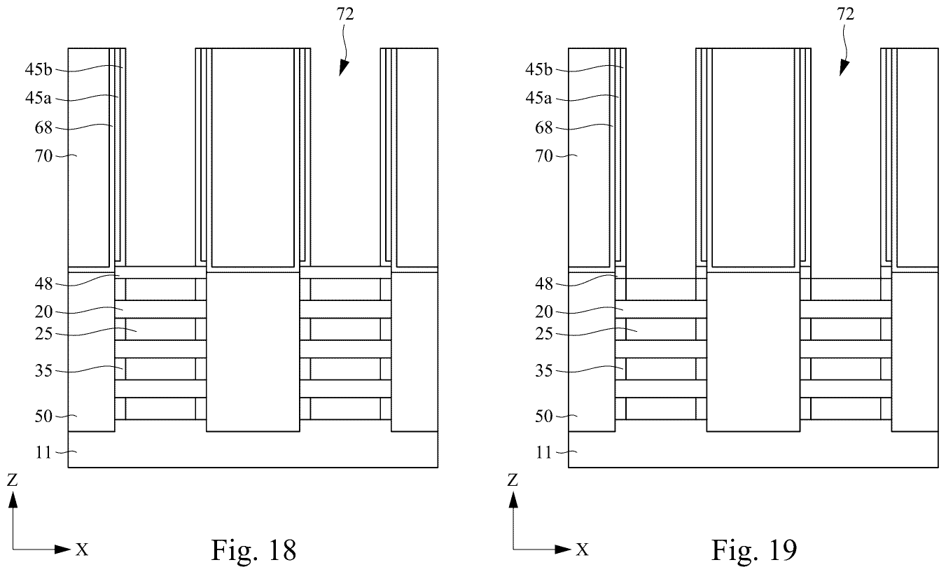

Then, as shown in FIG. 18, the sacrificial gate structures are removed forming a gate space 72, as disclosed herein with reference to FIG. 11. The remaining exposed portions of the etch stop layer 48 is subsequently removed by a process such as plasma dry etching and/or wet etching, as shown in FIG. 19.

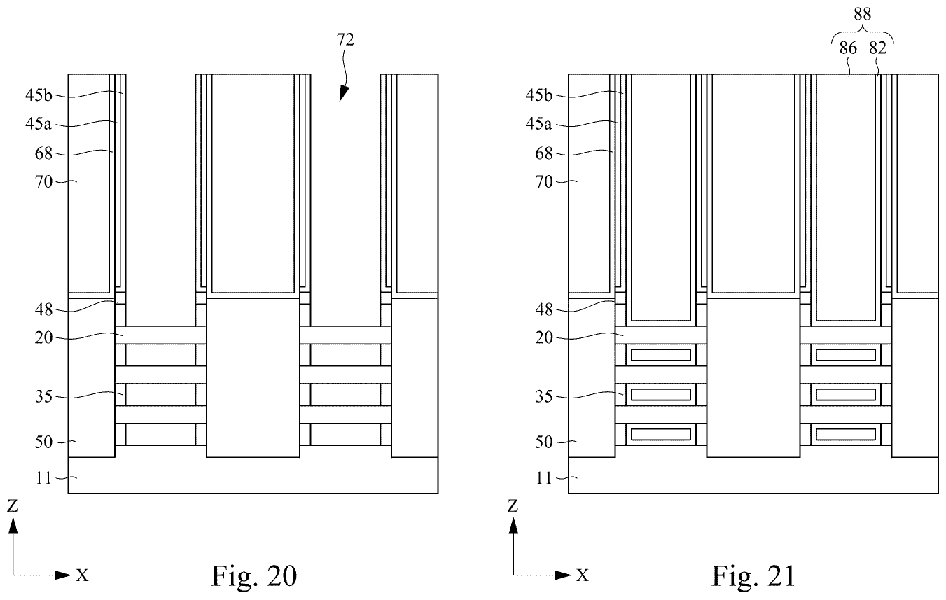

After the sacrificial gate structures and the etch stop layer 48 are removed, the second semiconductor layers 25 are removed, thereby forming nanowires or nanosheets (channel regions) of the first semiconductor layers 20 as shown in FIG. 20. Since the inner spacers 35 were previously formed, the etching of the second semiconductor layers 25 stops at the inner spacers 35. In other words, the inner spacers 35 may function as an etch-stop layer for etching of the second semiconductor layers 25. In some embodiments, the inner spacers 35 are etched after the second semiconductor layers are removed, as will be further explained, infra.

After the semiconductor nanowires or nanosheets (channel regions) of the first semiconductor layers 20 are formed, a metal gate structure 88 is formed as shown in FIG. 21, and as disclosed herein with reference to FIG. 13. In some embodiments, the structure and/or material of the gate electrode for the n-type GAA FET are different from the structure and/or material of the gate electrode for the p-type GAA FET.

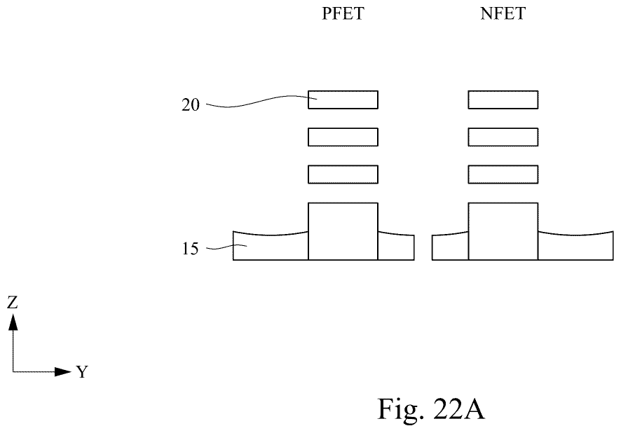

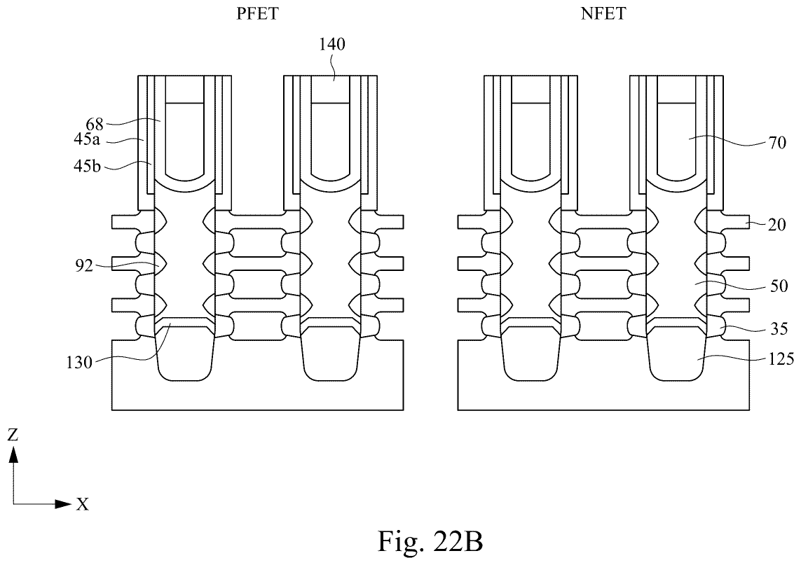

The etching of the inner spacers 35 after removal either the first or second semiconductor layers will now be explained in further detail. Semiconductor devices GAA FETs, including an n-type field effect transistor (NFET) and a p-type field effect transistor (PFET) will be used as an example, although it is understood the present disclosure is not limited to such devices. FIGS. 22A and 22B show an embodiment where the second semiconductor layers have been removed. FIG. 22A is a cross sectional view of the nanosheets 20 along the Y-axis direction and FIG. 22B is a cross sectional view of the PFET and NFET along the X-axis. While 3 nanosheets 20 are shown in each transistor, the number of nanosheets in each transistor ranges from 2 to about 20 in some embodiments, and from about 2 to about 10 in other embodiments. By adjusting the number of the semiconductor nanostructures (nanowires, nanosheets . . . etc), a driving current of the GAA FET device can be adjusted. In some embodiments, an undoped epitaxial region 125 is formed in the source/drain space before the source/drain 50 is formed. A dielectric layer 130 is formed between the undoped epitaxial region 125 and the source/drain 50 in some embodiments. In some embodiments, the dielectric layer 130 is an oxide or a nitride layer formed over the dielectric layer 130. In some embodiments, the oxide layer is formed by oxidizing the surface of the undoped epitaxial layer. In some embodiments, an ILD cap layer 140 is formed over the interlayer dielectric layer 70.

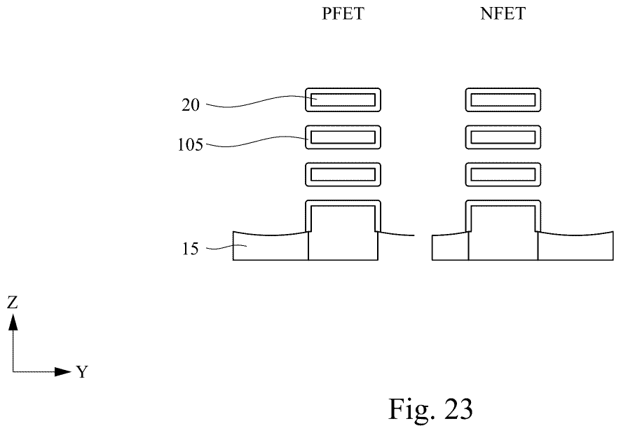

In some embodiments, a semiconductor cap layer 105 is formed over the nanosheets 20, as shown in FIG. 23. The semiconductor cap layer 105 is made of silicon in some embodiments. In some embodiments, the thickness of the semiconductor cap layer 105 ranges from about 4 Å to about 12 Å. In some embodiments, the thickness of the semiconductor cap layer 105 is about 8 Å. The semiconductor cap layer 105 is formed by a suitable deposition operation, such as CVD or ALD. By forming a semiconductor cap layer 105 around the nanosheet 20, the vertical distance between the nanosheets 20 can be reduced.

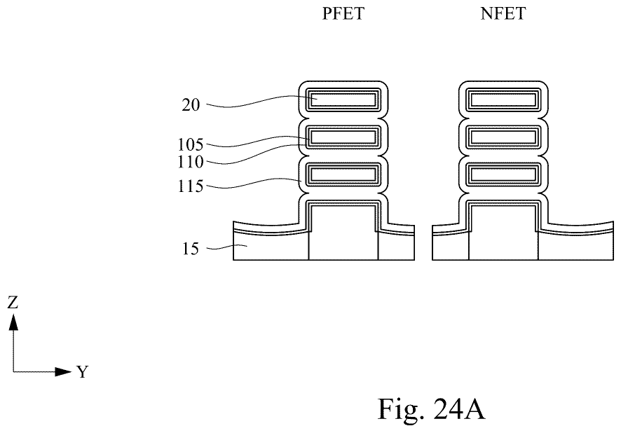

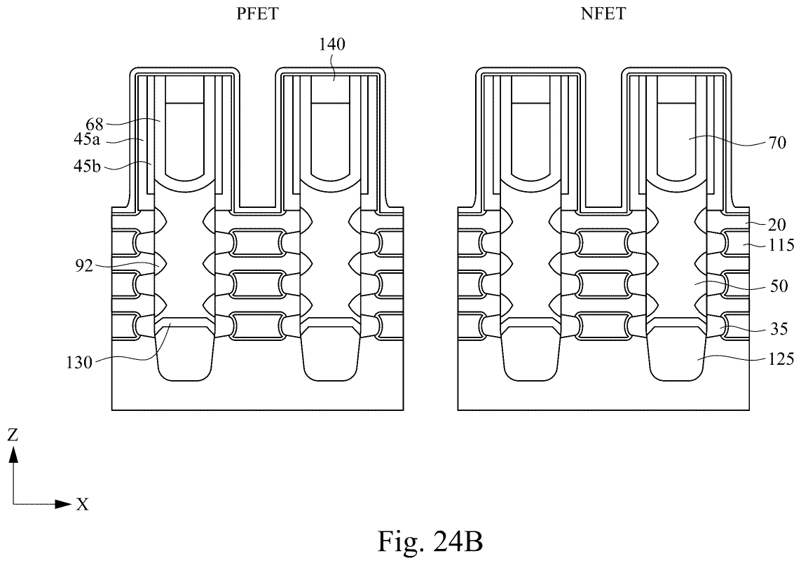

Then, as shown in FIGS. 24A and 24B, a high-k dielectric layer 110 is formed over the semiconductor cap layer 15 and a dipole layer 115 is formed over the high-k dielectric layer 110. In some embodiments, the dipole layer includes aluminum oxide. The dipole layer is used to adjust the voltage threshold Vt of the device. For example, the dipole layer can be used to transfer dipoles into the semiconductor cap layer 105 to adjust the Vt of the NFET.

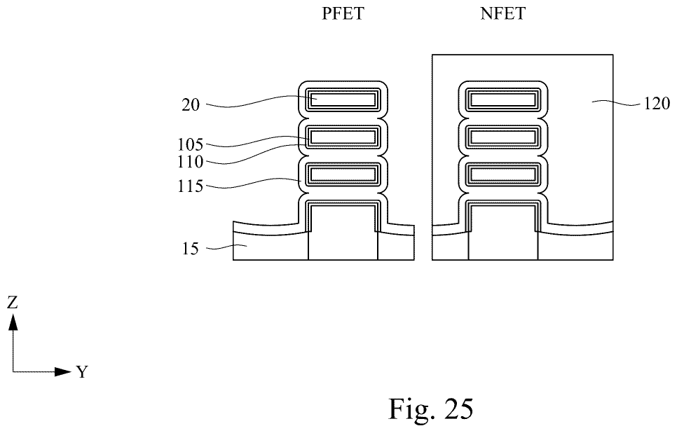

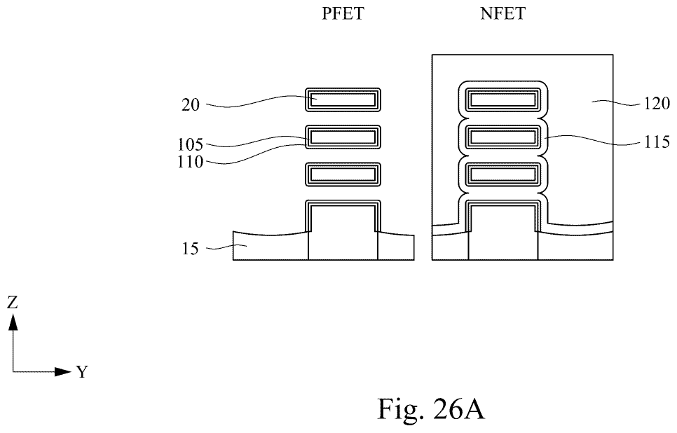

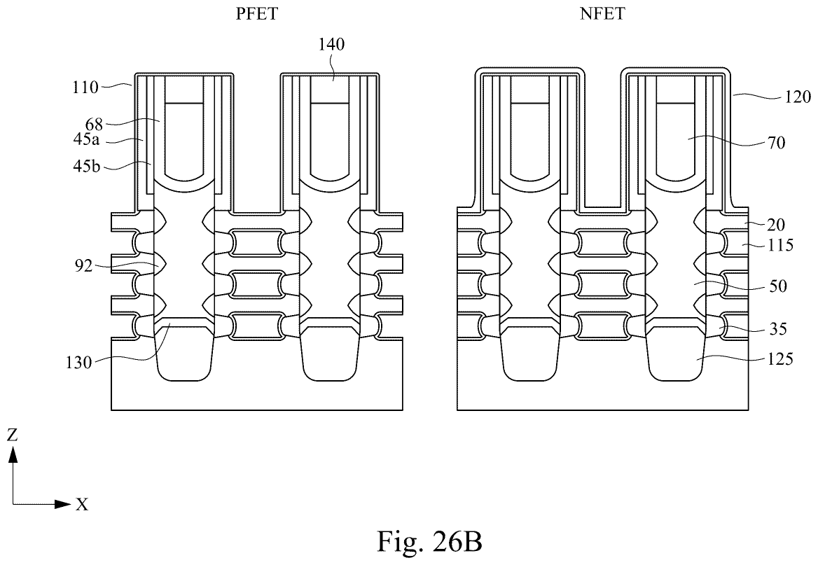

One of the FETs, such as the NFET, is subsequently masked, as shown in FIG. 25. Using photolithographic and etching operations, a mask layer 120 is formed over the NFET. In some embodiments, the mask layer 120 is a photoresist layer. In other embodiments, the mask layer 120 is a hard mask, such as silicon or a silicon oxide or nitride. The mask layer 120 is initially formed over both the PFET and the NFET in some embodiments, and then removed from over the PFET. After forming the mask layer 120 over the NFET, the dipole layer is removed from the over the PFET, as shown in FIGS. 26A and 26B. In some embodiments, a suitable etchant, such as a NH₄OH:H₂O₂:H₂O solution is used to remove the dipole layer.

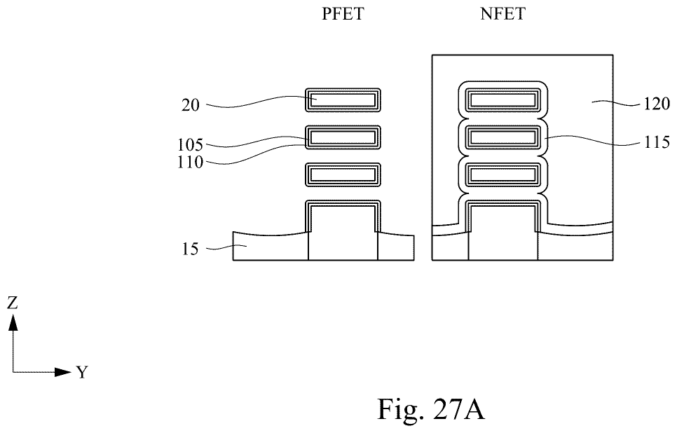

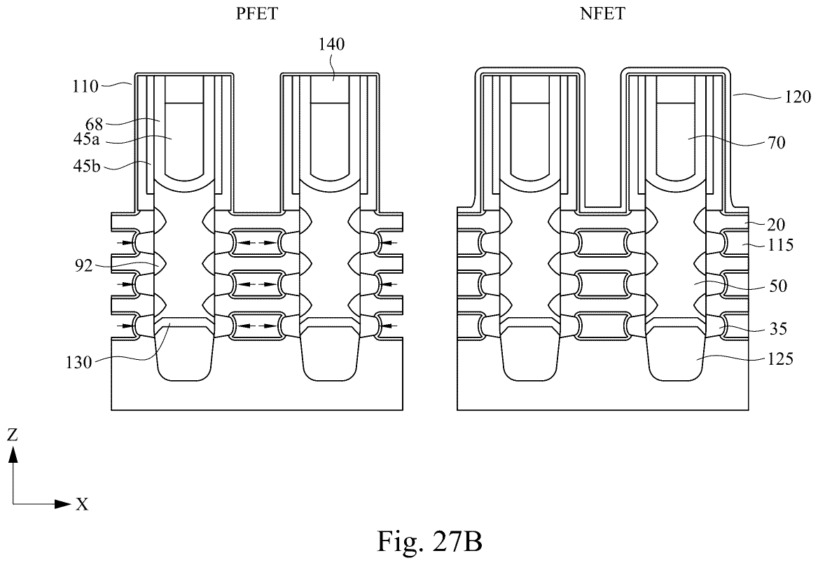

Next, the inner spacers 35 are etched or trimmed in the unmasked regions, such as the PFET region, as shown in FIGS. 27A and 27B. The high-k dielectric layer 110 is also etched in the unmasked regions in embodiments that include the high-k dielectric layer. In some embodiments, plasma etching is used to etch the high-k dielectric layer 110 and the inner spacers 35. In some embodiments, the plasma includes HF and NH₃. In some embodiments, the substrate or wafer is held by an electrostatic chuck at a temperature of about 40° C. to about 200° C. In some embodiments, the substrate or wafer is heated at temperature of about 200° C. to about 300° C. in a nitrogen ambient for about 50 s to about 100 s and then subjected to the etching plasma. In some embodiments, the etching plasma (e.g.—Hf and NH₃) is applied for about 50 s to about 100 s.

In some embodiments, the width of the inner spacers 35 in the unmasked areas are reduced or trimmed by about 0.5 nm to about 2 nm. In other embodiments the width of the inner spacers 35 are reduced or trimmed by about 0.1 nm to about 1 nm. Conversely, while the inner spacer widths are being reduced, the gate space lengths, and the gate lengths of subsequently formed gate electrodes, are increased by the inner spacer trimming operation.

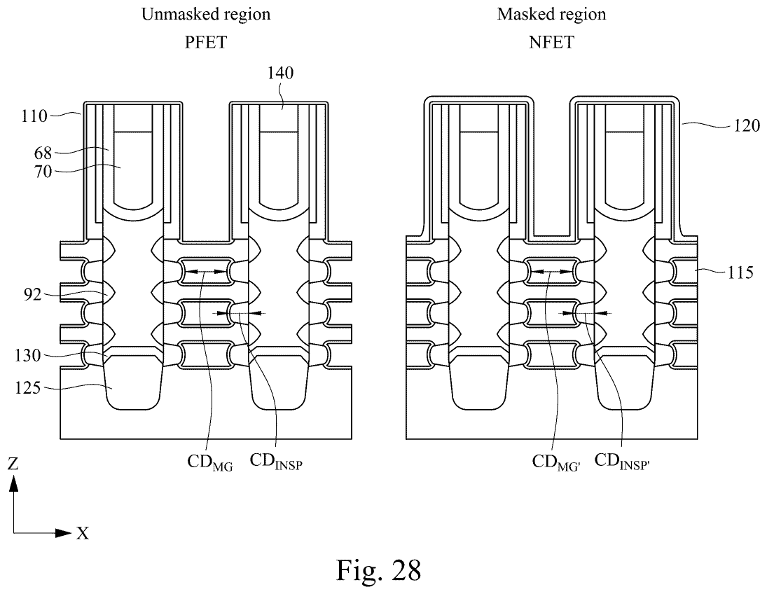

As shown in FIG. 28, the gate space lengths CD_{MG} of the unmasked, etched region is greater than the gate space lengths CD_{MG}′ of the masked region (CD_{MG}>CD_{MG}′), and the inner spacer widths CD_{INSP} in the unmasked etched region are less than the inner spacer widths CD_{INSP}′ of the masked region (CD_{INSP}<CD_{INSP}′). In other words, in this embodiment, the gate space lengths of the PFET are greater than the gate space lengths of the NFET, and the inner spacer widths of the PFET are less than the inner spacer widths of the NFET. In other embodiments, the PFET is masked, and the inner spacers of the NFET are etched or trimmed.

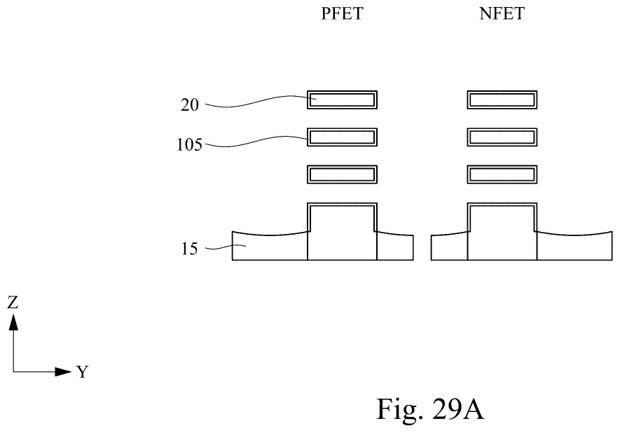

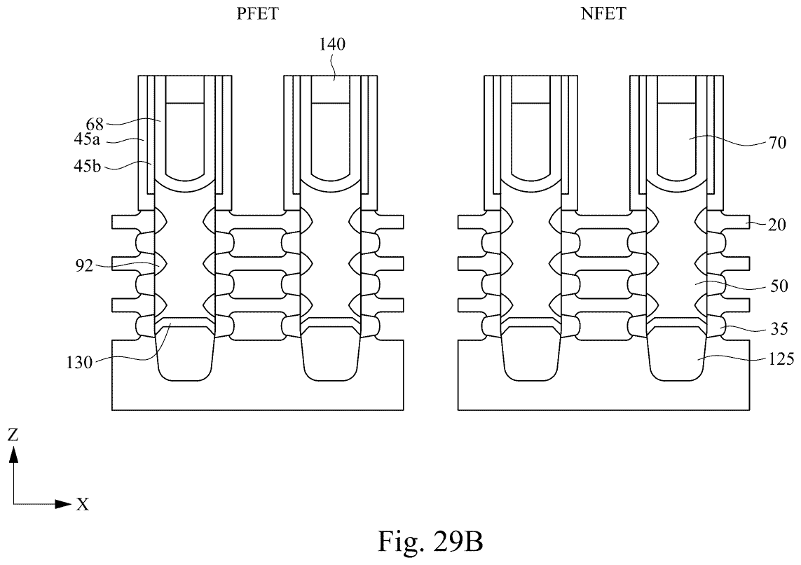

After the inner spacers are trimmed, the mask layer, dipole layer, and high-k dielectric layer are removed from the other transistor (NFET in this embodiment) as shown in FIGS. 29A and 29B. Then additional operations, including forming a gate structure 88, are performed as disclosed herein to provide a device as shown in FIG. 13.

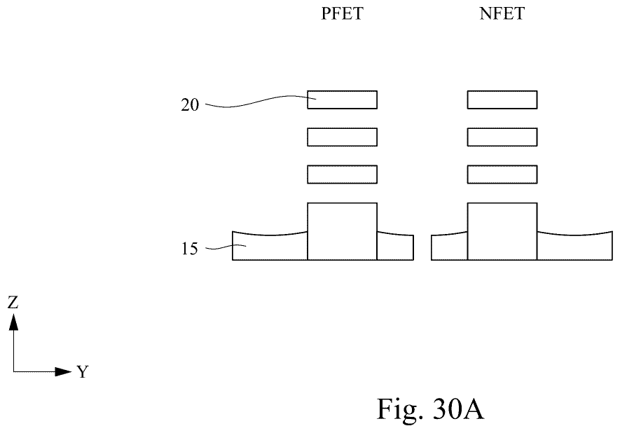

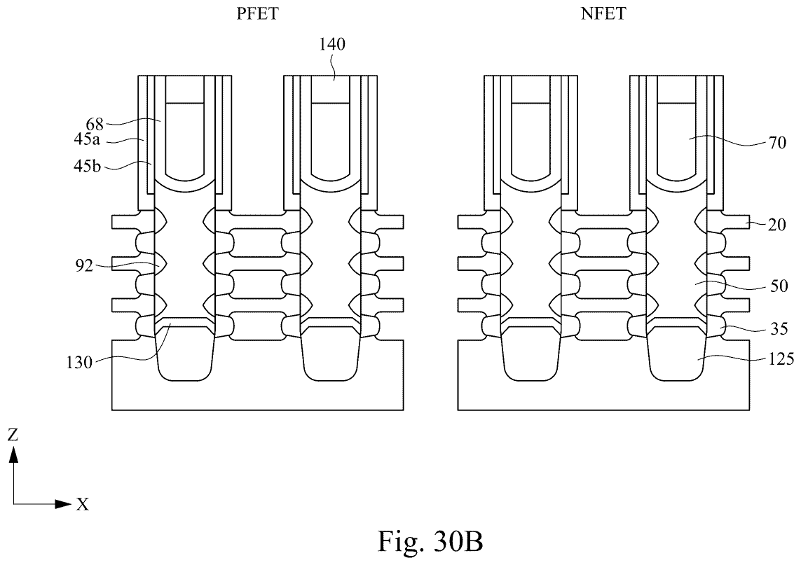

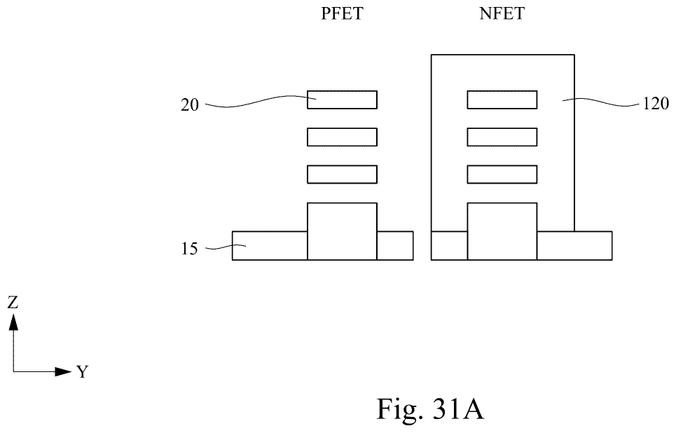

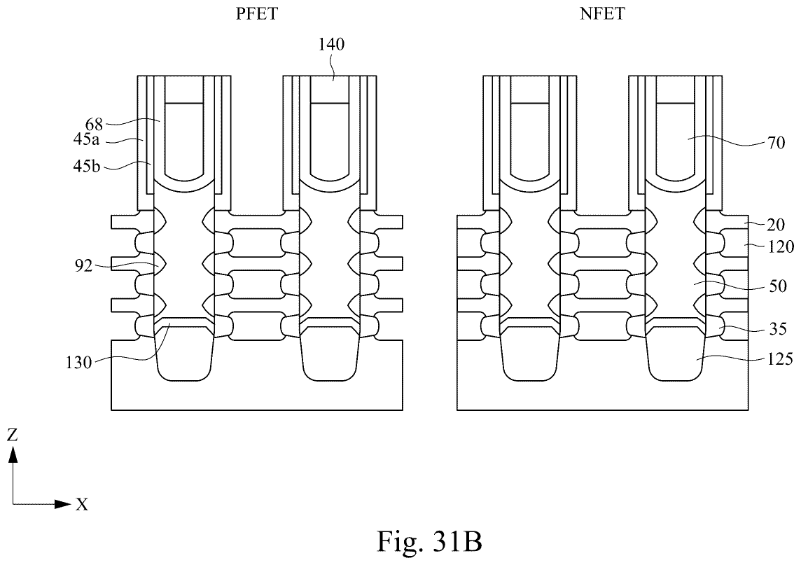

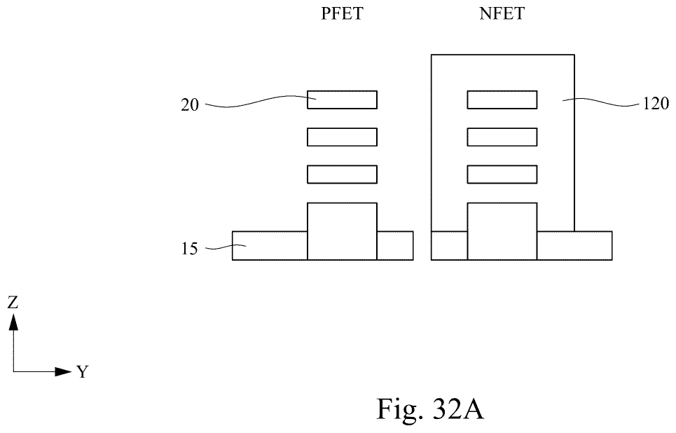

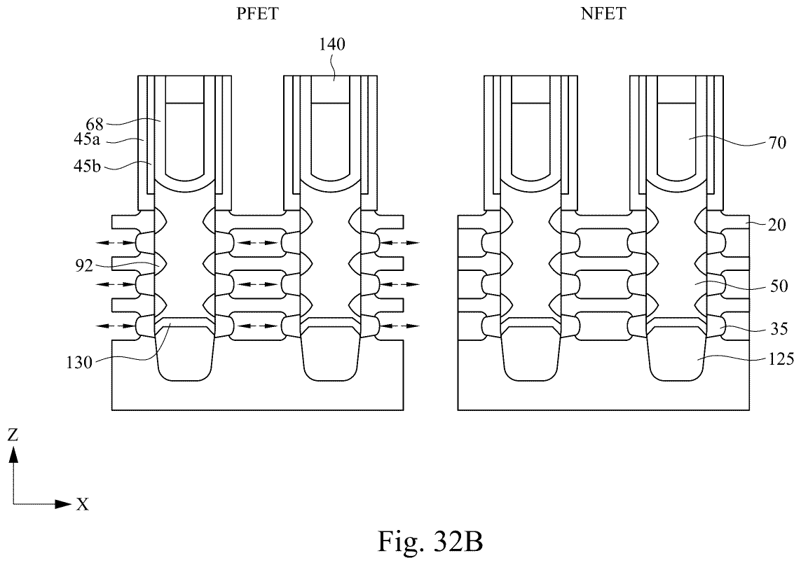

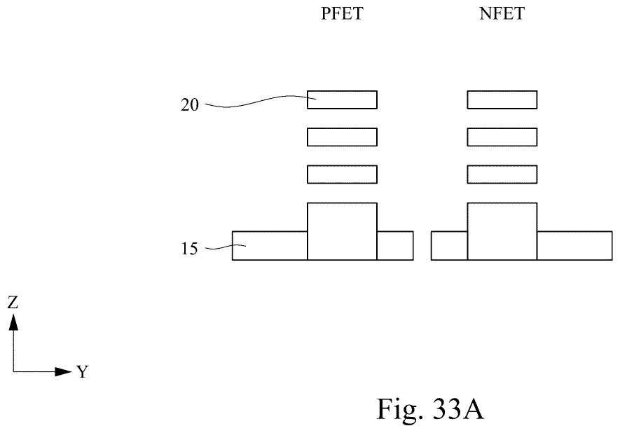

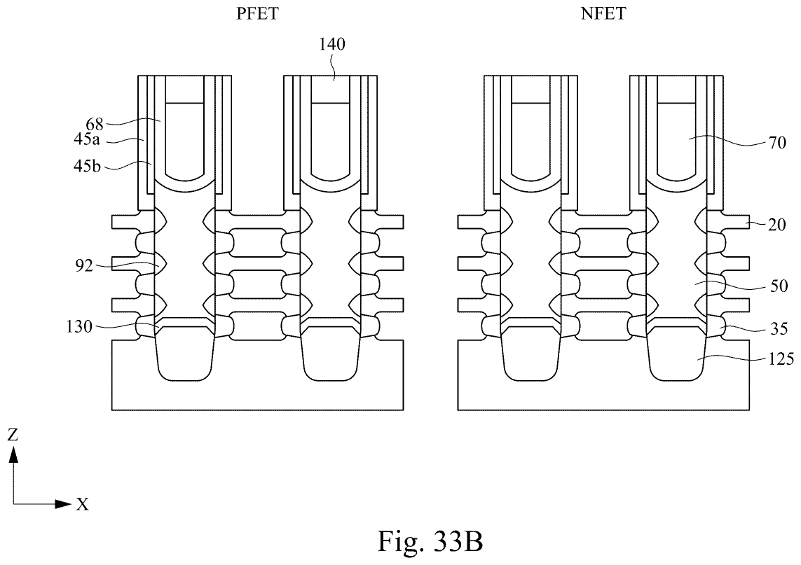

FIGS. 30A-33B illustrate another embodiment of manufacturing a semiconductor device according to embodiments of the present disclosure. In this embodiment, the semiconductor cap layer, high-k dielectric layer, and the dipole layer are not formed. The structures of FIGS. 30A and 30B correspond to the structures of FIGS. 22A and 22B. In FIGS. 31A and 31B, a mask layer 120 is formed over one of the transistor regions (in this embodiment the NFET) as disclosed herein in reference to FIG. 25. Then, the inner spacers 35 in the unmasked regions (the PFET in this embodiment) are etched, as shown in FIGS. 32A and 32B, and as disclosed herein in reference to FIGS. 27A and 27B. The mask layer is subsequently removed, as shown in FIGS. 33A and 33B, and as disclosed herein in reference to FIGS. 28A and 28B. Then additional operations, including forming a gate structure 88, are performed as disclosed herein to provide a device as shown in FIG. 13.

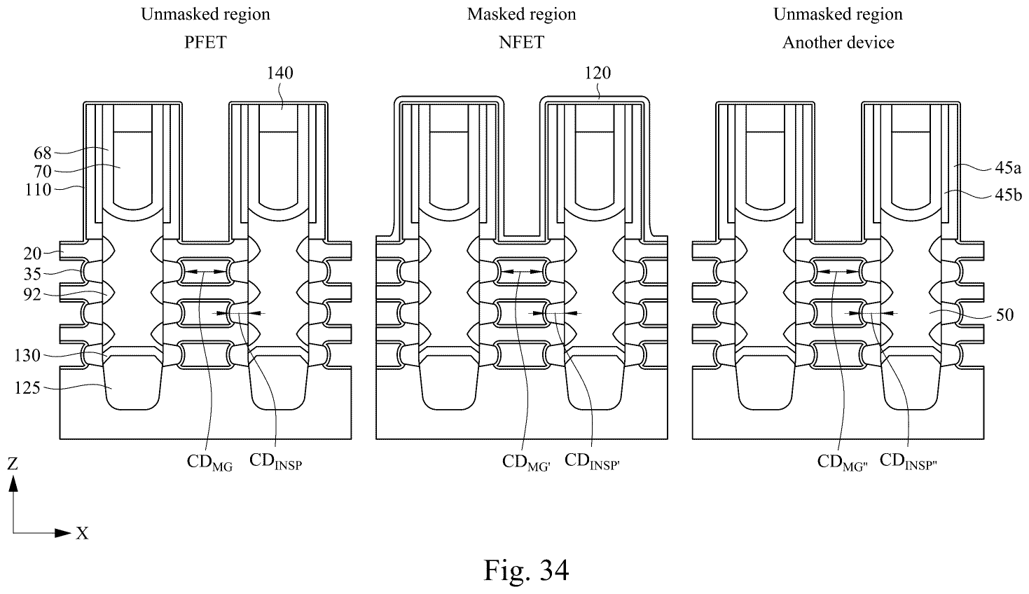

This disclosure is not limited to devices including two transistors. As illustrated in FIG. 34, the present disclosure includes embodiments having three or more transistors. For example, semiconductor devices according to the present disclosure may include a PFET, an NFET, and one or more additional transistors, which can be PFETs or NFETs. In this embodiment, the NFET is masked during the inner spacer etching operation, while the PFET and another device are unmasked. As a result, the gate space lengths CD_{MG}, CD_{MG}″ of the PFET and the another device, respectively, are about the same and are greater than the gate space lengths CD_{MG}′ of the NFET. In addition, the inner spacer widths CD_{INSP} and CD_{INSP}″ of the PFET and the another device, respectively are less than the inner spacer widths CD_{INSP}′ of the NFET.

In some embodiments: (CD_{MG}−CD_{MG}′)>about 0.1 nm to about 2 nm, (CD_{MG}″−CD_{MG}′)>about 0.1 nm to about 2 nm, and |CD_{MG}−CD_{MG}″|>about 0.1 nm to about 2 nm. In other embodiments: (CD_{MG}−CD_{MG}′)>about 0.2 nm to about 1 nm, (CD_{MG}″−CD_{MG}′)>about 0.2 nm to about 1 nm, and |CD_{MG}−CD_{MG}″|>about 0.2 nm to about 1 nm. In some embodiments: (CD_{INSP}′−CD_{INSP})>about 0.1 nm to about 2 nm, (CD_{INSP}′−CD_{INSP}″)>about 0.1 nm to about 2 nm, and |CD_{INSP}″−CD_{INSP}|>about 0.1 nm to about 2 nm. In other embodiments: (CD_{INSP}′−CD_{INSP})>about 0.2 nm to about 1 nm, (CD_{INSP}′−CD_{INSP}″)>about 0.2 nm to about 1 nm, and |CD_{INSP}″−CD_{INSP}|>about 0.2 nm to about 1 nm.

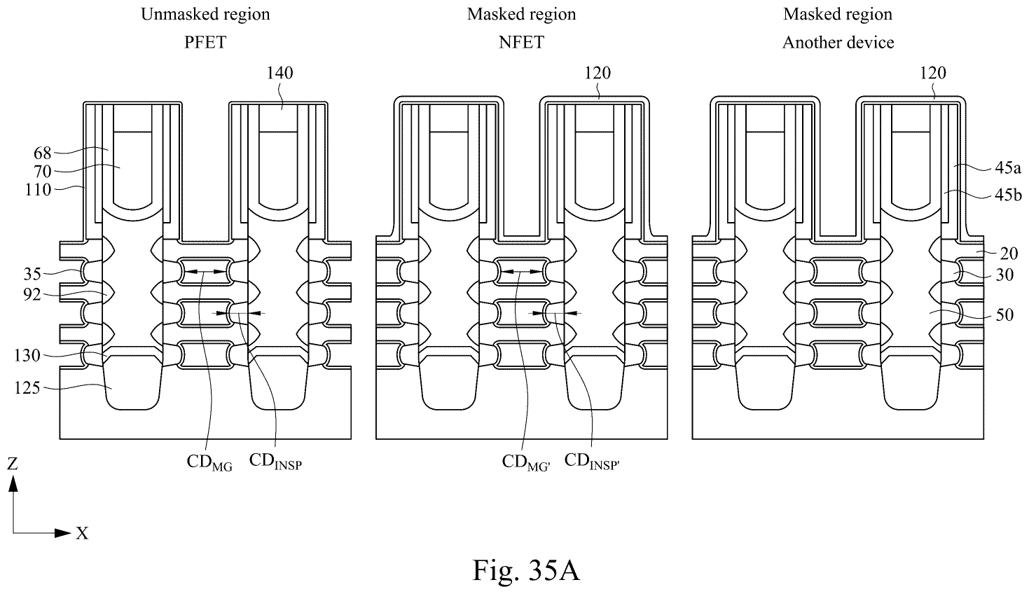

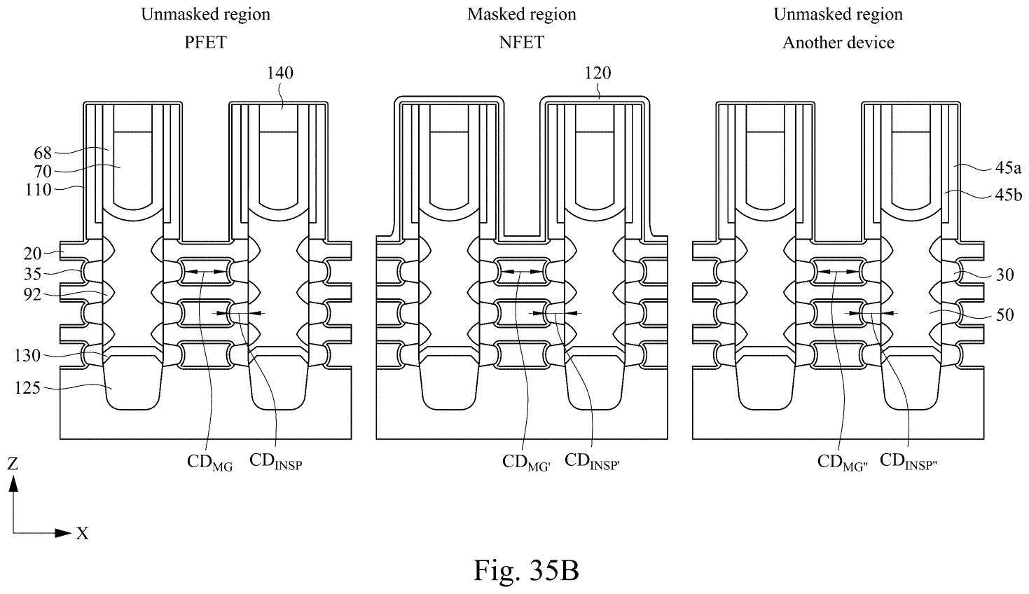

In another embodiment, as shown in FIGS. 35A and 35B, the NFET and the another device are masked during a first inner spacer etching operation, while the PFET is unmasked. Then, during a second inner spacing etching operation, the NFET is masked, and the PFET and the another device are unmasked. As a result, the gate space lengths CD_{MG} of the PFET are greater than the gate space lengths CD_{MG}″ of the another device and the gate space lengths CD_{MG}″ of the another device are greater than the gate space lengths CD_{MG}′ of the NFET (CD_{MG}>CD_{MG}″>CD_{MG}′). In addition, the inner spacer widths CD_{INSP} of the PFET are less than the inner spacer widths CD_{INSP}″ of the another device and the inner spacer widths CD_{INSP}″ are less than the inner spacer widths CD_{INSP}′ of the NFET (CD_{INSP}<CD_{INSP}″<CD_{INSP}′). In other embodiments, the NFET is unmasked during the first and second inner spacer trimming operations and the PFET is masked during the trimming operations.

In some embodiments, when CD_{MG}>CD_{MG}″>CD_{MG}′ and CD_{INSP}<CD_{INSP}″<CD_{INSP}′:(CD_{MG}−CD_{MG}′)>about 0.1 nm to about 2 nm, (CD_{MG}″−CD_{MG}′)>about 0.1 nm to about 2 nm, (CD_{MG}−CD_{MG}″)>about 0.1 nm to about 2 nm, (CD_{INSP}′−CD_{INSP})>about 0.1 nm to about 2 nm, (CD_{INSP}′−CD_{INSP}″)>about 0.1 nm to about 2 nm, and (CD_{INSP}″−CD_{INSP})>about 0.1 nm to about 2 nm. In other embodiments: (CD_{MG}−CD_{MG}′)>about 0.2 nm to about 1 nm, (CD_{MG}″−CD_{MG}′)>about 0.2 nm to about 1 nm, (CD_{MG}−CD_{MG}″)>about 0.2 nm to about 1 nm, (CD_{INSP}′−CD_{INSP})>about 0.2 nm to about 1 nm, (CD_{INSP}′−CD_{INSP}″)>about 0.2 nm to about 1 nm, and (CD_{INSP}″−CD_{INSP})>about 0.2 nm to about 1 nm.

In some embodiments, when CD_{MG}″>CD_{MG}>CD_{MG}′ and CD_{INSP}″<CD_{INSP}<CD_{INSP}′:|CD_{INSP}′−CD_{INSP}|>about 0.1 nm to about 2 nm, |CD_{INSP}′−CD_{INSP}″|>about 0.1 nm to about 2 nm, and |CD_{INSP}″−CD_{INSP}|>about 0.1 nm to about 2 nm. In other embodiments: |CD_{INSP}′−CD_{INSP}|>about 0.2 nm to about 1 nm, |CD_{INSP}′−CD_{INSP}″|>about 0.2 nm to about 1 nm, and |CD_{INSP}″−CD_{INSP}|>about 0.2 nm to about 1 nm.

Because gate electrodes are subsequently formed in the gate spaces between the gate sidewall spacers 45 and the inner spacers 35, the subsequently formed gate lengths along the X-direction correspond to the gate spaces. Semiconductor devices formed according the present disclosure include a plurality of multilayer stacks of alternating semiconductor layers 20 and gate structures 88 (see FIG. 21). The multilayer stacks may be different types of semiconductor devices. For example, in some embodiments, a first multilayer stack is part of a PFET and a second multilayer stack is part of an NFET. As explained above, because the inner spacers 35 in some of the multilayer stacks are trimmed and the inner spacers 35 in other multilayer stacks are not trimmed, the gate electrodes formed in the resulting gate spaces in the various multilayer stacks may be different. For example, the gate lengths between the inner spacers 35 in the multilayer stacks that undergo the trimming operation according to this disclosure are longer than the gate lengths of the gate electrodes between the untrimmed spacers. In some embodiments, a ratio of a gate length in a first multilayer stack that does not undergo the inner spacer trimming operation disclosed herein to a gate length in a second multilayer stack that undergoes the inner spacer trimming operation disclosed herein ranges from about 0.5 to about 0.99. In other embodiments, the ratio of the gate length in the first multilayer stack to the gate length in the second multilayer stack ranges from about 0.8 to about 0.96. Similarly, a ratio of a width of the dielectric spacers in the second multilayer stack that undergoes the inner spacer trimming operation disclosed herein to a width of the dielectric spacers in the second multilayer stack that does not undergo the trimming operation ranges from about 0.67 to about 0.99 in some embodiments, and the ratio of the width of the dielectric spacers in the first multilayer stack to the width of the dielectric spacers in the second multilayer stack ranges from about 0.78 to about 0.93 in other embodiments. Similarly, if one multilayer stack undergoes a greater amount of inner spacer trimming than another multilayer stack, the disclosed ranges of ratios of the gate lengths and inner spacer widths are similarly obtained. At gate length ratios and inner spacer ratios outside the disclosed ranges there may not be significant improvement in the DC performance of the GAA FET device.

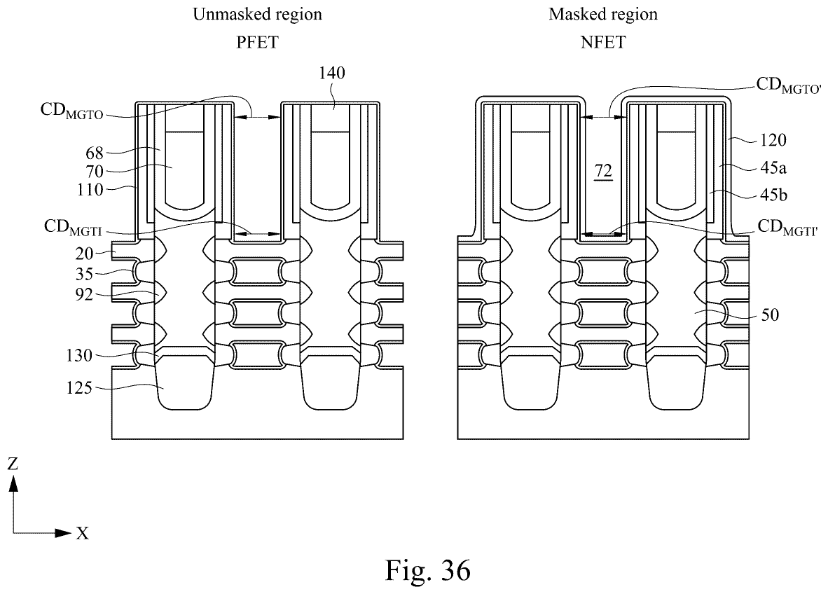

In some embodiments, the gate sidewall spacer 45, or first gate sidewall spacer 45a where there are more than one gate sidewall spacer, is etched during the inner spacer trimming operation because of low etch selectivity between the gate sidewall spacers and the inner spacers. In some embodiments, the outer or upper portion of the gate sidewall spacers is etched more than an inner or lower portion of the gate sidewall spacers. As shown in FIG. 36, the length CD_{MGTO} of the outer portion of the gate space is greater than the length CD_{MGTI} of the inner portion of the gate space (CD_{MGTO}>CD_{MGTI}). In some embodiments, the length CD_{MGTO} of the outer portion of the gate space is about 0.1 nm to about 2 nm greater than the lengths CD_{MGTI} of the inner portion of the gate space. In other embodiments, the difference between CD_{MGTO} and CD_{MGTI} is about 0.2 nm to about 1 nm. In some embodiments, the differences between the lengths CD_{MGTO} and CD_{MGTI} of the outer and inner portions of the gate space of the unmasked regions is greater than differences in lengths CD_{MGTO}′ and CD_{MGTI}′ of the outer and inner portions of the gate space of the masked regions [(CD_{MGTO}−CD_{MGTI})> (CD_{MGTO}′−CD_{MGTI}′)]. In some embodiments, the differences in lengths CD_{MGTO} and CD_{MGTI} and CD_{MGTO}′ and CD_{MGTI}′ of the outer portion and inner portions of the gate spaces of the unmasked and masked regions is about 0.1 nm to about 2 nm {[(CD_{MGTO}−CD_{MGTI})−(CD_{MGTO}′−CD_{MGTI}′)]=0.1 nm to 2 nm}, and in other embodiments, the difference is about 0.2 nm to about 1 nm {[(CD_{MGTO}−CD_{MGTI})−(CD_{MGTO}′−CD_{MGTI}′)]=about 0.2 nm to about 1 nm}.

If there is sufficiently high etch selectivity between the gate sidewall spacers and the inner spacers then there would be no, or not a significant amount of, etching of the gate sidewall spacers during the inner spacer trimming. In some embodiments, the gate space 72 becomes bowl shaped during the inner spacer etching operation.

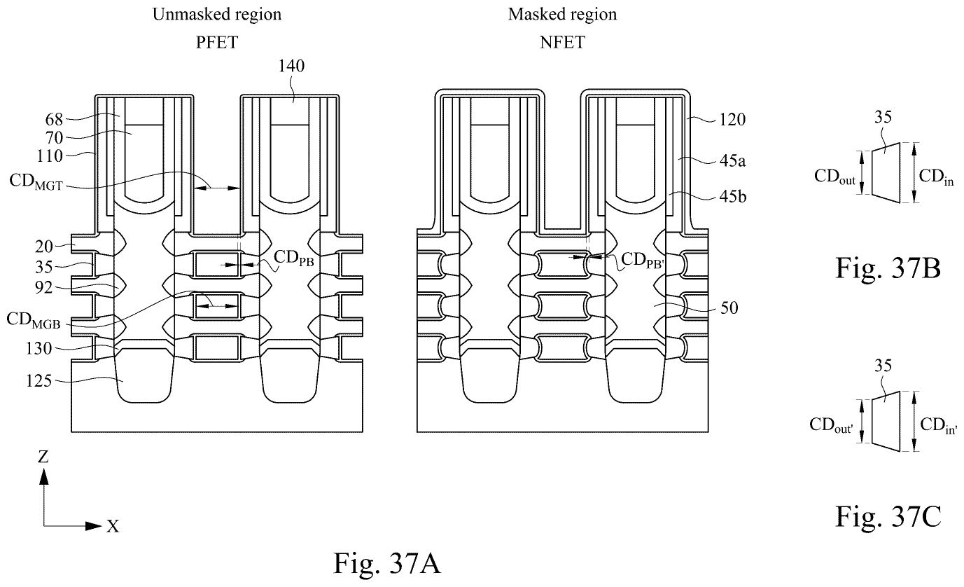

In some embodiments, as shown in FIG. 37A, when the length CD_{MGT} of the gate space 72 between the gate sidewall spacers 45 is close to the length CD_{MGB} of the gate space between the inner spacers 35 a difference between the gate sidewall spacer surface and the inner surface of the inner spacer 35 along the X-direction (or pullback) in the gate space is produced. On the other hand, if the length CD_{MGT} of the gate space 72 between the gate sidewall spacers 45 is not close to the length CD_{MGB} of the gate space between the inner spacers 35 the pullback in the gate space between the inner spacers 35 is not produced. In some embodiments, when the absolute value of the difference of the length CD_{MGT} of the gate space between the gate sidewall spacers 45 and the length CD_{MGB} of the gate space between the inner spacers 35 is less than about 0.2 nm to about 1 nm: (1) the length CD_{PB} of the pullback at the inner spacers 35 of the unmasked region is greater than about 0.2 nm to about 1 nm, (2) the length CD_{PB}′ of the pullback of the inner spacers 35 in the masked region is less than about 0.2 nm to about 1 nm, and (3) the difference in the lengths CD_{PB}, CD_{PB}′ of the pullback of the inner spacers of the unmasked and masked regions, respectively, is greater than about 0.2 nm to about 1 nm (when |CD_{MGT}−CD_{MGB}|<about 0.2 nm to about 1 nm: (1) CD_{PB}>about 0.2 nm to about 1 nm, (2) CD_{PB}′<about 0.2 nm to about 1 nm, and (3) (CD_{PB}−CD_{PB}′)>about 0.2 nm to about 1 nm).

In some embodiments, the inner spacers 35 are substantially trapezoid shaped, as shown in FIGS. 37B and 37C. The inner parallel side of the trapezoid shaped inner spacer is the longer parallel side of the trapezoid, and the opposing shorter parallel side faces the source drain region. In some embodiments, the difference in length CDᵢₙ, CDₒᵤₜ of the parallel sides of the inner spacers 35 of the unmasked, etched regions is less than about 3 Å (CDᵢₙ−CDₒᵤₜ<about 3 Å). On the other hand, the difference in length CDᵢₙ′, CDₒᵤₜ′ of the parallel sides of the inner spacers 35 of the masked regions is greater than about 3 Å (CDᵢₙ−CDₒᵤₜ>about 3 Å).

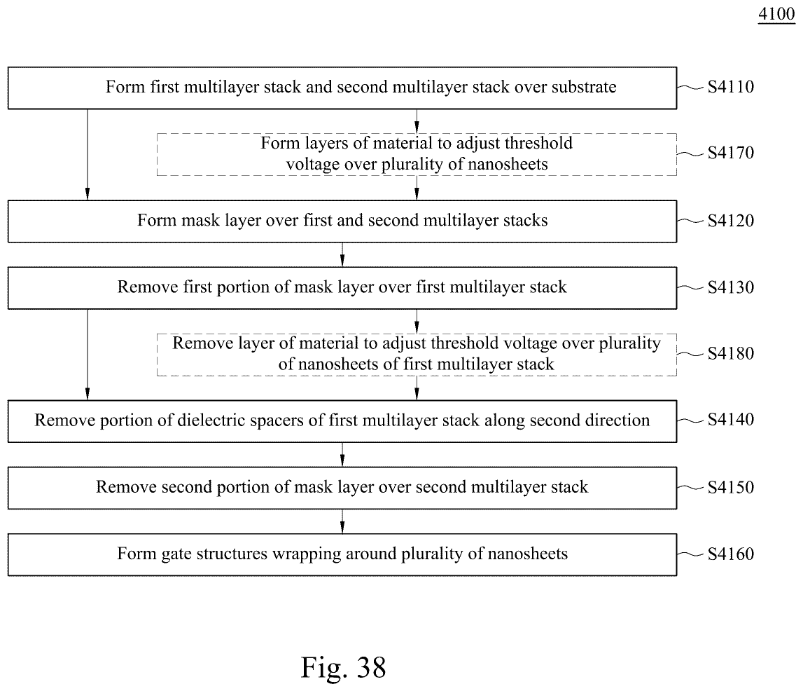

FIG. 38 shows a flow chart for a method 4100 of manufacturing a semiconductor device according to embodiments of the present disclosure. The method of manufacturing a semiconductor device includes an operation S4110 of forming a first multilayer stack and a second multilayer stack over a substrate. The first and second multilayer stacks include a plurality of spaced apart nanosheets 20 arranged along a first direction of the stack, and dielectric spacers 35 disposed between adjacent nanosheets. A mask layer 120 is formed over the first and second multilayer stacks in operation S4120. Then, in operation S4130, a first portion of the mask layer over the first multilayer stack is removed to expose the plurality of nanosheets 20 and the dielectric spacers 35 of the first multilayer stack. In operation S4140, a portion of the dielectric spacers of the first multilayer stack along a second direction perpendicular to the first direction of the stack is removed to decrease a thickness of the dielectric spacers of the first multilayer stack along the second direction. A second portion of the mask layer over the second multilayer stack is subsequently removed in operation S4150 to expose the plurality of nanosheets and dielectric spacers of the second multilayer stack, and gate structures are wrapped around the plurality of nanosheets of the first multilayer stack and the plurality of nanosheets of the second multilayer stack in operation S4160. In some embodiments, before forming the mask layer, layers of a material to adjust a threshold voltage are formed over the plurality of nanosheets of the first and second multilayer stacks in operation S4170. In some embodiments, after removing the first portion of the mask layer over the first multilayer stack, the layer of the material to adjust the threshold voltage over the plurality of nanosheets of the first multilayer stack is removed in operation S4180.

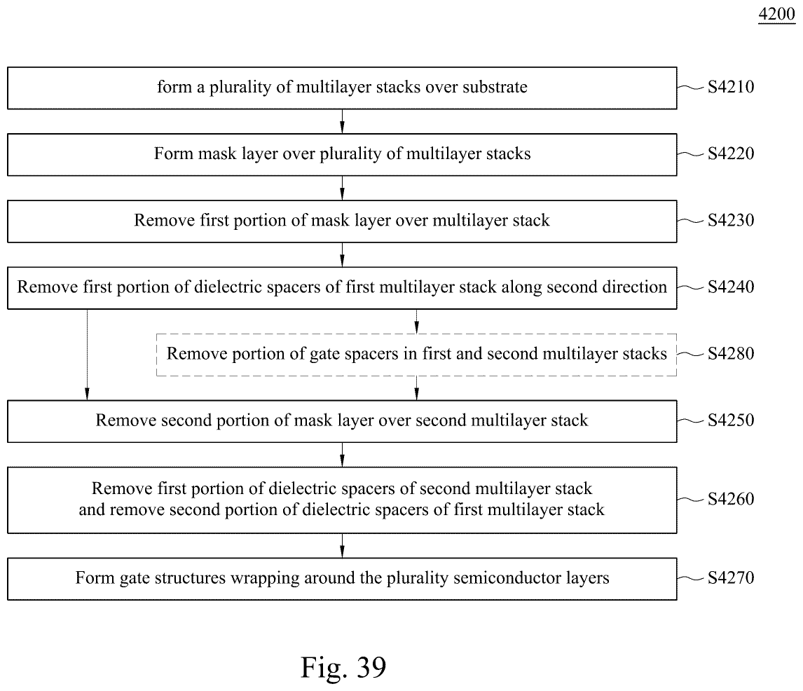

FIG. 39 shows a flow chart for a method 4200 of manufacturing a semiconductor device according to embodiments of the present disclosure. The method of manufacturing a semiconductor device includes an operation S4210 of forming a plurality of multilayer stacks over a substrate. Each of the plurality of multilayer stacks includes a plurality of spaced apart semiconductor layers arranged along a first direction of the stack; and dielectric spacers disposed between adjacent semiconductor layers. A mask layer is formed over the plurality of multilayer stacks in operation S4220. A first portion of the mask layer over a multilayer stack is removed in operation S4230 to expose the plurality of semiconductor layers and the dielectric spacers of the first multilayer stack. Next, in operation S4240, a first portion of the dielectric spacers of the first multilayer stack is removed along a second direction perpendicular to the first direction of the stack to decrease a thickness of the first dielectric spacers of the first multilayer stack along the second direction. Then, a second portion of the mask layer over a second multilayer stack is removed to expose the plurality of semiconductor layers of the second multilayer stack in operation S4250. A first portion of the dielectric spacers of the second multilayer stack and a second portion of the dielectric spacers of the first multilayer stack are subsequently removed in operation S4260. In operation S4270, gate structures are formed wrapping around the plurality of semiconductor layers of the first multilayer stack and the plurality of semiconductor layers of the second multilayer stack. In some embodiments, a portion of gate spacers in the first and second multilayer stacks are removed in operation S4280.

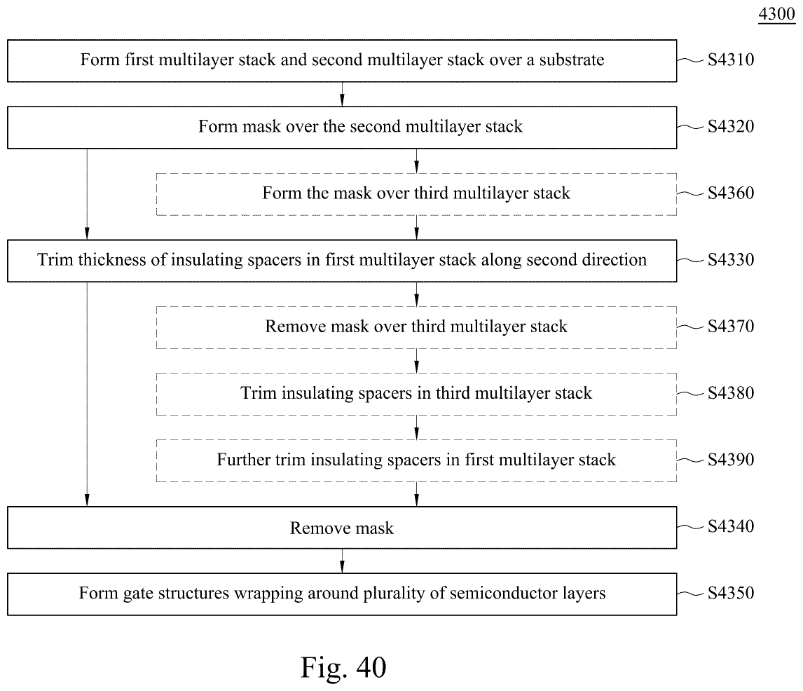

FIG. 40 shows a flow chart for a method 4300 of manufacturing a semiconductor device according to embodiments of the present disclosure. The method of manufacturing a semiconductor device includes an operation S4310 of forming a first multilayer stack and a second multilayer stack over a substrate. The first and second multilayer stacks include a plurality of spaced apart semiconductor layers arranged along a first direction of the stack, and insulating spacers disposed between adjacent semiconductor layers. A mask is formed over the second multilayer stack in operation S4320. Then, a thickness of the insulating spacers in the first multilayer stack is trimmed along a second direction perpendicular to the first direction in operation S4330. In operation S4340, the mask is removed to expose the plurality of semiconductor layers and insulating spacers of the second multilayer stack. Gate structures are subsequently formed wrapping around the plurality of the semiconductor layers of the first multilayer stack and the plurality of semiconductor layers of the second multilayer stack in operation S4350. In some embodiments, the method includes forming the mask over of a third multilayer stack in operation S4360. In some embodiments, the method includes, before removing the mask to expose the plurality of semiconductor layers and insulating spacers of the second multilayer stack, removing the mask over the third multilayer stack in operation S4370; trimming insulating spacers in the third multilayer stack in operation S4380; and further trimming the insulating spacers in the first multilayer stack in operation S4390.

Additional operations may be performed on the structure of FIG. 21, forming electrical contacts to the gate electrodes and source regions, including silicide layers. Additional insulating layers and metal wiring layers, including interconnects and vias may be formed over the structure of FIG. 21. The structure of FIG. 21 may be part of a larger integrated circuit, including additional devices and components.

In embodiments of the disclosure, the width of inner spacers between the gate electrode and the source/drain regions of a GAA FET are reduced, thereby reducing the capacitance of the inner spacer between the gate electrodes and the source/drain regions, and improving the DC performance of the GAA FET device. In some embodiments of the disclosure, the width of the inner spacer is optimized for different transistors within a semiconductor device. Embodiments of the disclosure allow localized control of the inner spacer widths gate electrode lengths of various transistors in a semiconductor device. Embodiments of the disclosure also allow localized control of the voltage threshold Vt of various transistors in semiconductor device.

It will be understood that not all advantages have been necessarily discussed herein, no particular advantage is required for all embodiments or examples, and other embodiments or examples may offer different advantages.

An embodiment of the disclosure is a method of manufacturing a semiconductor device including forming a first multilayer stack and a second multilayer stack over a substrate. The first and second multilayer stacks include a plurality of spaced apart nanosheets arranged along a first direction of the stack, and dielectric spacers disposed between adjacent nanosheets. A mask layer is formed over the first and second multilayer stacks. A first portion of the mask layer over the first multilayer stack is removed to expose the plurality of nanosheets and the dielectric spacers of the first multilayer stack. A portion of the dielectric spacers of the first multilayer stack along a second direction perpendicular to the first direction of the stack is removed to decrease a thickness of the dielectric spacers of the first multilayer stack along the second direction. A second portion of the mask layer over the second multilayer stack is removed to expose the plurality of nanosheets and dielectric spacers of the second multilayer stack, and gate structures are wrapped around the plurality of nanosheets of the first multilayer stack and the plurality of nanosheets of the second multilayer stack. In an embodiment, before forming the mask layer, layers of a material to adjust a threshold voltage are formed over the plurality of nanosheets of the first and second multilayer stacks. In an embodiment, the method includes after removing the first portion of the mask layer over the first multilayer stack, removing the layers of the material to adjust the threshold voltage over the plurality of nanosheets of the first multilayer stack. In an embodiment, the plurality of nanosheets comprise a semiconductor material. In an embodiment, the gate structures include a high-k gate dielectric layer wrapping around the plurality of nanosheets of the first and second multilayer stacks. In an embodiment, the gate structures further include a metal gate layer disposed over the high-k gate dielectric layer. In an embodiment, a ratio of a gate length in the second multilayer stack to a gate length in the first multilayer stack ranges from 0.5 to 0.99. In an embodiment, a ratio of a gate length in the second multilayer stack to a gate length in the first multilayer stack ranges from 0.8 to 0.96. In an embodiment, the removing a portion of the dielectric spacers includes a plasma etching operation.

Another embodiment of the disclosure is a method of manufacturing a semiconductor device, including forming a plurality of multilayer stacks over a substrate. Each of the plurality of multilayer stacks includes a plurality of spaced apart semiconductor layers arranged along a first direction of the stack; and dielectric spacers disposed between adjacent semiconductor layers. A mask layer is formed over the plurality of multilayer stacks. A first portion of the mask layer over a multilayer stack is removed to expose the plurality of semiconductor layers and the dielectric spacers of the first multilayer stack. A first portion of the dielectric spacers of the first multilayer stack is removed along a second direction perpendicular to the first direction of the stack to decrease a thickness of the first dielectric spacers of the first multilayer stack along the second direction. A second portion of the mask layer over a second multilayer stack is removed to expose the plurality of semiconductor layers of the second multilayer stack. A first portion of the dielectric spacers of the second multilayer stack is removed and a second portion of the dielectric spacers of the first multilayer stack is removed. Gate structures are formed wrapping around the plurality of semiconductor layers of the first multilayer stack and the plurality of semiconductor layers of the second multilayer stack. In an embodiment, the gate structures include a high-k gate dielectric layer wrapping around the plurality of semiconductor layers of the first and second multilayer stacks. In an embodiment, the gate structures further include a metal gate layer disposed over the high-k gate dielectric layer. In an embodiment, removing portions of the dielectric spacers of the first and second multilayer stacks includes plasma etching operations. In an embodiment, the method includes removing a portion of gate spacers in the first and second multilayer stacks. In an embodiment, a ratio of a gate length in the second multilayer stack to a gate length in the first multilayer stack ranges from 0.5 to 0.99.

Another embodiment of the disclosure is a method of manufacturing a semiconductor device, including forming a first multilayer stack and a second multilayer stack over a substrate. The first and second multilayer stacks include a plurality of spaced apart semiconductor layers arranged along a first direction of the stack, and insulating spacers disposed between adjacent semiconductor layers. A mask is formed over the second multilayer stack. A thickness of the insulating spacers in the first multilayer stack is trimmed along a second direction perpendicular to the first direction. The mask is removed to expose the plurality of semiconductor layers and insulating spacers of the second multilayer stack. Gate structures are formed wrapping around the plurality of the semiconductor layers of the first multilayer stack and the plurality of semiconductor layers of the second multilayer stack. In an embodiment, the method includes forming the mask over of a third multilayer stack. In an embodiment, the method includes, before removing the mask to expose the plurality of semiconductor layers and insulating spacers of the second multilayer stack, removing the mask over the third multilayer stack; trimming insulating spacers in the third multilayer stack; and further trimming the insulating spacers in the first multilayer stack. In an embodiment, a ratio of a width of the insulating spacers in the second multilayer stack to a width of the insulating spacers in the first multilayer stack ranges from 0.67 to 0.99. In an embodiment, a thickness of insulating spacers along the second direction in the third multilayer stack is less than a thickness the insulating spacers along the second direction in the second multilayer stack and greater than a thickness of the insulating spacers of the first multilayer stack after forming the gate structures.

Another embodiment of the disclosure is a semiconductor device, including a first multilayer stack and a second multilayer stack disposed over a substrate. The first and second multilayer stacks include: a plurality of spaced apart nanosheets arranged along a first direction of the stack; dielectric spacers disposed between adjacent nanosheets; and gate structures having a gate length wrapping around the plurality of nanosheets of the first multilayer stack and the plurality of nanosheets of the second multilayer stack. A ratio of a gate length in the second multilayer stack to a gate length in the first multilayer stack ranges from 0.5 to 0.99. In an embodiment, a ratio of a gate length in the second multilayer stack to a gate length in the first multilayer stack ranges from 0.8 to 0.96. In an embodiment, the second multilayer stack includes a layer of a material to adjust a threshold voltage disposed over the plurality of nanosheets. In an embodiment, the plurality of nanosheets include a semiconductor material. In an embodiment, the gate structures include a high-k gate dielectric layer wrapping around the plurality of nanosheets of the first and second multilayer stacks. In an embodiment, the gate structures further include a metal gate layer disposed over the high-k gate dielectric layer. In an embodiment, a ratio of a width of the dielectric spacers in the first multilayer stack to a width of the dielectric spacers in the second multilayer stack ranges from 0.67 to 0.99. In an embodiment, a ratio of a width of the dielectric spacers in the first multilayer stack to a width of the dielectric spacers in the second multilayer stack ranges from 0.78 to 0.93.

Another embodiment of the disclosure is a semiconductor device, including a plurality of multilayer stacks disposed over a substrate. Each of the plurality of multilayer stacks include: a plurality of spaced apart semiconductor layers arranged along a first direction of the stack; dielectric spacers disposed between adjacent semiconductor layers; and gate structures wrapping around the plurality of semiconductor layers of the multilayer stacks. The plurality of multilayer stacks include a first multilayer stack and a second multilayer stack. A gate length of the first multilayer stack along a second direction perpendicular to the first direction is greater than a gate length of the second multilayer stack along the second direction. In an embodiment, a width of the dielectric spacers of the first multilayer stack along the second direction is less than a width of the dielectric spacers of the second multilayer stack along the second direction. In an embodiment, the gate structures include a high-k gate dielectric layer wrapping around the plurality of semiconductor layers of the first and second multilayer stacks. In an embodiment, the gate structures further include a metal gate layer disposed over the high-k gate dielectric layer. In an embodiment, the device includes source/drain regions disposed over ends of the plurality of multilayer stacks along the second direction, and the source/drain regions are arranged along the first direction. In an embodiment, the first multilayer stack is part a first conductivity type field effect transistor and the second multilayer is a part of a second conductivity type field effect transistor, and the first conductivity type and second conductivity type are different.

Another embodiment of the disclosure is a semiconductor device, including a first multilayer stack, a second multilayer stack, and a third multilayer stack disposed over a substrate. The first, second, and third multilayer stacks, include: a plurality of spaced apart semiconductor layers arranged along a first direction of the stack; insulating spacers disposed between adjacent semiconductor layers; and gate structures wrapping around the plurality of the semiconductor layers of the first, second, and third multilayer stacks. A width of the insulating spacers along a second direction crossing the first direction of the second multilayer stack is less than a width of the insulating spacers of the first multilayer stack along the second direction and greater than a width of the insulating spacers of the third multilayer stack along the second direction. In an embodiment, the gate structures include high-k gate dielectric layers wrapping around the plurality of semiconductor layers and gate electrodes wrapping around the gate dielectric layers. In an embodiment, a length of a gate electrode in the second direction of the second multilayer stack is greater than a length of a gate electrode in the second direction of the first multilayer stack and less than a length of a gate electrode in the second direction of the third multilayer stack. In an embodiment, a ratio of the length of the gate electrodes in the third multilayer stack to the length of the gate electrodes in the first multilayer stack ranges from 0.5 to 0.99. In an embodiment, a ratio of the length of the gate electrodes in the third multilayer stack to the length of the gate electrodes in the first multilayer stack ranges from 0.8 to 0.96. In an embodiment, a ratio of a width of the insulating spacers in the third multilayer stack to a width of the insulating spacers in the first multilayer stack ranges from 0.67 to 0.99.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a first multilayer stack and a second multilayer stack over a substrate,
wherein the first and second multilayer stacks, comprise:
a plurality of spaced apart nanosheets arranged along a first direction of the stack; and
dielectric spacers disposed between adjacent nanosheets;
forming a mask layer over the first and second multilayer stacks;
removing a first portion of the mask layer over the first multilayer stack to expose the plurality of nanosheets and the dielectric spacers of the first multilayer stack;
removing a portion of the dielectric spacers of the first multilayer stack along a second direction perpendicular to the first direction of the stack to decrease a thickness of the dielectric spacers of the first multilayer stack along the second direction;
removing a second portion of the mask layer over the second multilayer stack to expose the plurality of nanosheets and dielectric spacers of the second multilayer stack; and
forming gate structures wrapping around the plurality of nanosheets of the first multilayer stack and the plurality of nanosheets of the second multilayer stack.

2. The method according to claim 1, further comprising before forming the mask layer, forming layers of a material to adjust a threshold voltage over the plurality of nanosheets of the first and second multilayer stacks.

3. The method according to claim 2, further comprising after removing the first portion of the mask layer over the first multilayer stack, removing the layers of the material to adjust the threshold voltage over the plurality of nanosheets of the first multilayer stack.

4. The method according to claim 1, wherein the plurality of nanosheets comprise a semiconductor material.

5. The method according to claim 1, wherein the gate structures include a high-k gate dielectric layer wrapping around the plurality of nanosheets of the first and second multilayer stacks.

6. The method according to claim 5, wherein the gate structures further include a metal gate layer disposed over the high-k gate dielectric layer.

7. The method according to claim 1, wherein a ratio of a gate length in the second multilayer stack to a gate length in the first multilayer stack ranges from 0.5 to 0.99.

8. The method according to claim 1, wherein a ratio of a gate length in the second multilayer stack to a gate length in the first multilayer stack ranges from 0.8 to 0.96.

9. The method according to claim 1, wherein the removing a portion of the dielectric spacers comprises a plasma etching operation.

10. A method of manufacturing a semiconductor device, comprising:
forming a plurality of multilayer stacks over a substrate,
wherein each of the plurality of multilayer stacks comprise:
a plurality of spaced apart semiconductor layers arranged along a first direction of the stack; and
dielectric spacers disposed between adjacent semiconductor layers;
forming a mask layer over the plurality of multilayer stacks;
removing a first portion of the mask layer over a multilayer stack to expose the plurality of semiconductor layers and the dielectric spacers of the first multilayer stack;
removing a first portion of the dielectric spacers of the first multilayer stack along a second direction perpendicular to the first direction of the stack to decrease a thickness of the first dielectric spacers of the first multilayer stack along the second direction;
removing a second portion of the mask layer over a second multilayer stack to expose the plurality of semiconductor layers of the second multilayer stack;
removing a first portion of the dielectric spacers of the second multilayer stack and removing a second portion of the dielectric spacers of the first multilayer stack; and
forming gate structures wrapping around the plurality of semiconductor layers of the first multilayer stack and the plurality of semiconductor layers of the second multilayer stack.

11. The method according to claim 10, wherein the gate structures include a high-k gate dielectric layer wrapping around the plurality of semiconductor layers of the first and second multilayer stacks.

12. The method according to claim 11, wherein the gate structures further include a metal gate layer disposed over the high-k gate dielectric layer.

13. The method according to claim 10, wherein removing portions of the dielectric spacers of the first and second multilayer stacks comprises plasma etching operations.

14. The method according to claim 10, further comprising removing a portion of gate spacers in the first and second multilayer stacks.

15. The method according to claim 11, wherein a ratio of a gate length in the second multilayer stack to a gate length in the first multilayer stack ranges from 0.5 to 0.99.

16. A semiconductor device, comprising:
a first multilayer stack and a second multilayer stack disposed over a substrate,
wherein the first and second multilayer stacks, comprise:
a plurality of spaced apart nanosheets arranged along a first direction of the stack;
dielectric spacers disposed between adjacent nanosheets; and
gate structures having a gate length wrapping around the plurality of nanosheets of the first multilayer stack and the plurality of nanosheets of the second multilayer stack,
wherein a ratio of a gate length in the second multilayer stack to a gate length in the first multilayer stack ranges from 0.5 to 0.99.

17. The semiconductor device of claim 16, wherein a ratio of a gate length in the second multilayer stack to a gate length in the first multilayer stack ranges from 0.8 to 0.96.

18. The semiconductor device of claim 16, wherein the second multilayer stack further comprises a layer of a material to adjust a threshold voltage disposed over the plurality of nanosheets.

19. The semiconductor device of claim 16, wherein the plurality of nanosheets comprise a semiconductor material.

20. The semiconductor device of claim 16, wherein the gate structures include a high-k gate dielectric layer wrapping around the plurality of nanosheets of the first and second multilayer stacks.
